(19) United States
(12) Patent Application Publication
(10) Pub. No.: US 2025/0247074 A1
(43) Pub. Date: Jul. 31, 2025

(54) BULK ACOUSTIC WAVE RESONATOR, MANUFACTURING METHOD THEREOF AND ELECTRONIC DEVICE

(71) Applicants: Beijing BOE Technology Development Co., Ltd., Beijing (CN); BOE TECHNOLOGY GROUP CO., LTD., Beijing (CN)

(72) Inventor: Xiyuan WANG, Beijing (CN)

(21) Appl. No.: 18/694,970

(22) PCT Filed: Jul. 19, 2023
(86) PCT No.: PCT/CN2023/108018

§ 371 Date: Mar. 23, 2024

(51) Int. Cl. H03H 9/17; H03H 3/02; H03H 9/02

(52) U.S. Cl. CPC H03H 9/174; H03H 3/02; H03H 9/175; H03H 2003/023; H03H 2003/025; H03H 2009/02196

(57) ABSTRACT

A bulk acoustic wave resonator, a method for manufacturing the same and an electronic device are provided, and belong to the field of communication technology. The bulk acoustic wave resonator includes: a base substrate, a first electrode, a piezoelectric layer, and a second electrode. The bulk acoustic wave resonator further includes: a first bias resistance layer on a side of the first electrode close to the base substrate, and a first electric isolation layer between the first bias resistance layer and the first electrode; the first bias resistance layer is made of a material with a high resistivity; and/or a second bias resistance layer on a side of the second electrode away from the base substrate, and a second electric isolation layer between the second bias resistance layer and the second electrode; and the second bias resistance layer is made of a material with a high resistivity.

### TECHNICAL FIELD

The present disclosure relates to the field of communication technology, and in particular to a bulk acoustic wave resonator, a method for manufacturing a bulk acoustic wave resonator and an electronic device.

### BACKGROUND

In the field of mobile communications, the allocated total available frequency is in a narrow range, and there are many frequency bands used for the mobile communication, so that a spacing between adjacent frequency bands is narrow (about several MHz (megahertz) to tens of MHz), and a single frequency band has a narrow bandwidth (tens of MHz). Thus, a filter used in a mobile phone is required to have performance characteristics of a small in-band ripple, a large out-of-band rejection, and a good rectangularity. A conventional micro-strip filter has a large volume, an insufficient out-of-band rejection and a poor rectangularity and cannot meet the above requirement: a cavity filter has a large volume and cannot meet the above requirement: a dielectric filter has a large in-band insertion loss and a poor rectangularity and cannot meet the above requirement: an IPD (Integrated Passive Device) filter has a large in-band ripple and a poor rectangularity and cannot meet the above requirement.

A bulk acoustic wave resonator serves as an elementary unit of a structure of a bulk acoustic wave filter. The existing bulk acoustic wave resonator adopts a silicon wafer as a material of a base substrate with a sandwich structure, including a first electrode, a piezoelectric layer and a second electrode from bottom to top. The first electrode and the second electrode are metal electrodes, and the piezoelectric layer is made of a piezoelectric material.

An operating principle of the bulk acoustic wave resonator is: a radio frequency signal enters into the resonator from an electrode at one end of the resonator, then is converted into an acoustic wave signal of mechanical vibration at an interface of the piezoelectric material and the metal electrode through an inverse piezoelectric effect; the acoustic wave signal is formed as a resonant standing wave with a certain frequency in the sandwich structure including the first electrode, the piezoelectric layer and the second electrode; a frequency of the radio frequency signal is the same as a resonant frequency of the resonator; the acoustic wave signal is transmitted to the electrode at the other end of the resonator, and is converted into the radio frequency signal at the interface of the metal electrode and the piezoelectric material through a piezoelectric effect. The resonator has a fixed resonant frequency. When the frequency of the radio frequency signal is the same as the resonant frequency of the resonator, the conversion from the radio frequency signal to the acoustic wave signal to the radio frequency signal is high-efficiency; when the frequency of the radio frequency signal is not the same as the resonant frequency of the resonator, the conversion from the radio frequency signal to the acoustic wave signal to the radio frequency signal is low-efficiency, and most of the radio frequency signals cannot be transmitted through the resonator. That is, the resonator functions as a filter, which filters the radio frequency signals. In order to reduce the insertion loss during the filtering process, it is necessary to limit the acoustic wave signal as much as possible inside the piezoelectric material, to prevent the acoustic wave signal from spreading out. Therefore, acoustic wave reflectors are generally formed on upper and lower surfaces of the resonator.

### SUMMARY

The present disclosure aims to solve at least one technical problem in the prior art, and provides a bulk acoustic wave resonator, a method for manufacturing a bulk acoustic wave resonator and an electronic device.

The embodiment of the present disclosure provides a bulk acoustic wave resonator, including: a base substrate, a first electrode, a piezoelectric layer, and a second electrode; wherein the first electrode is on the base substrate, the second electrode is on a side of the first electrode away from the base substrate, the piezoelectric layer is between the first electrode and the second electrode; and orthographic projections of any two of the first electrode, the piezoelectric layer and the second electrode on the base substrate at least partially overlap with each other; wherein the bulk acoustic wave resonator further includes: a first bias resistance layer on a side of the first electrode close to the base substrate, and a first electric isolation layer between the first bias resistance layer and the first electrode; wherein the first bias resistance layer is made of a material with a high resistivity; and/or a second bias resistance layer on a side of the second electrode away from the base substrate, and a second electric isolation layer between the second bias resistance layer and the second electrode; wherein the second bias resistance layer is made of a material with a high resistivity.

In the embodiment of the present disclosure, the base substrate includes a first cavity penetrating through the base substrate in a thickness direction of the base substrate.

In the embodiment of the present disclosure, the bulk acoustic wave resonator further includes at least one mirror structure on a side of the base substrate close to the first electrode; wherein the first bias resistance layer is arranged on the base substrate, the at least one mirror structure is arranged on a side of the first bias resistance layer close to the base substrate; and each mirror structure includes a first sub-structure and a second sub-structure sequentially arranged along a direction away from the base substrate, and an acoustic impedance of a material of the first sub-structure is greater than that of a material of the second sub-structure.

In the embodiment of the present disclosure, the bulk acoustic wave resonator includes the first bias resistance layer, and the first bias resistance layer is a single layer structure made of any one of ITO, IZO, ZnO, IGO, IGZO, W, Mn, Cr, Ti, Ni, constantan alloy, manganin alloy, nichrome alloy, or iron-chromium-aluminum alloy, or a stack made of any multiple ones of ITO, IZO, ZnO, IGO, IGZO, W, Mn, Cr, Ti, Ni, constantan alloy, manganin alloy, nichrome alloy, or iron-chromium-aluminum alloy.

In the embodiment of the present disclosure, the bulk acoustic wave resonator includes the second bias resistance layer, and the second bias resistance layer is a single layer structure made of any one of ITO, IZO, ZnO, IGO, IGZO, W, Mn, Cr, Ti, Ni, constantan alloy, manganin alloy, nichrome alloy, iron-chromium-aluminum alloy, or a stack made of any multiple ones of ITO, IZO, ZnO, IGO, IGZO, W, Mn, Cr, Ti, Ni, constantan alloy, manganin alloy, nichrome alloy, iron-chromium-aluminum alloy.

In the embodiment of the present disclosure, the bulk acoustic wave resonator includes the first electrical isolation layer, and the first electrical isolation layer is a single layer structure made of any one of Si₃N₄, SiO₂, Al₂O₃, AlN, or BN, or a stack made of any multiple ones of Si₃N₄, SiO₂, Al₂O₃, AlN, or BN.

In the embodiment of the present disclosure, the bulk acoustic wave resonator includes the second electrical isolation layer, and the second electrical isolation layer is a single layer structure made of any one of Si₃N₄, SiO₂, Al₂O₃, AlN, or BN, or a stack made of any multiple ones of Si₃N₄, SiO₂, Al₂O₃, AlN, or BN.

In the embodiment of the present disclosure, the base substrate is made of any one of glass, Si, sapphire, SiC, GaAs, GaN, InP, BN, ZnO, or GaO.

In the embodiment of the present disclosure, the piezoelectric layer is made of any one of AlN, doped AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF, wherein the doped AlN includes any one of Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N.

In the embodiment of the present disclosure, each of the first electrode and the second electrode is made of any one of Mo, Al, Cu, Co, Ag, Ti, Pt, Ru, W, or Au.

The embodiment of the present disclosure provides a method for manufacturing a bulk acoustic wave resonator, including; sequentially forming a first electrode, a piezoelectric layer and a second electrode on a first base substrate, wherein orthographic projections of any two of the first electrode, the piezoelectric layer and the second electrode on the first base substrate at least partially overlap with each other; wherein the method further includes; forming a first bias resistance layer on a side of the first electrode close to the base substrate, and forming a first electric isolation layer between the first bias resistance layer and the first electrode; wherein the first bias resistance layer is made of a material with a high resistivity; and/or forming a second bias resistance layer on a side of the second electrode away from the base substrate, and forming a second electric isolation layer between the second bias resistance layer and the second electrode; wherein the second bias resistance layer is made of a material with a high resistivity.

In the embodiment of the present disclosure, the method further includes: processing the base substrate to form a first cavity penetrating through the base substrate in a thickness direction of the base substrate.

In the embodiment of the present disclosure, the method further includes: forming at least one mirror structure on a side of the base substrate close to the first electrode; wherein the first bias resistance layer is formed on the base substrate, the at least one mirror structure is formed on a side of the first bias resistance layer close to the base substrate; and the forming the at least one mirror structure includes sequentially forming a first sub-structure and a second sub-structure along a direction away from the base substrate, and an acoustic impedance of a material of the first sub-structure is greater than that of a material of the second sub-structure.

In the embodiment of the present disclosure, the bulk acoustic wave resonator includes the first bias resistance layer, and the first bias resistance layer is a single layer structure made of any one of ITO, IZO, ZnO, IGO, IGZO, W, Mn, Cr, Ti, Ni, constantan alloy, manganin alloy, nichrome alloy, or iron-chromium-aluminum alloy, or a stack made of any multiple ones of ITO, IZO, ZnO, IGO, IGZO, W, Mn, Cr, Ti, Ni, constantan alloy, manganin alloy, nichrome alloy, or iron-chromium-aluminum alloy.

In the embodiment of the present disclosure, the bulk acoustic wave resonator includes the second bias resistance layer, and the second bias resistance layer is a single layer structure made of any one of ITO, IZO, ZnO, IGO, IGZO, W, Mn, Cr, Ti, Ni, constantan alloy, manganin alloy, nichrome alloy, iron-chromium-aluminum alloy, or a stack made of any multiple ones of ITO, IZO, ZnO, IGO, IGZO, W, Mn, Cr, Ti, Ni, constantan alloy, manganin alloy, nichrome alloy, iron-chromium-aluminum alloy.

In the embodiment of the present disclosure, the bulk acoustic wave resonator includes the first electrical isolation layer, and the first electrical isolation layer is a single layer structure made of any one of Si₃N₄, SiO₂, Al₂O₃, AlN, or BN, or a stack made of any multiple ones of Si₃N₄, SiO₂, Al₂O₃, AlN, or BN.

In the embodiment of the present disclosure, the bulk acoustic wave resonator includes the second electrical isolation layer, and the second electrical isolation layer is a single layer structure made of any one of Si₃N₄, SiO₂, Al₂O₃, AlN, or BN, or a stack made of any multiple ones of Si₃N₄, SiO₂, Al₂O₃, AlN, or BN.

In the embodiment of the present disclosure, the base substrate is made of any one of glass, Si, sapphire, SiC, GaAs, GaN, InP, BN, ZnO, or GaO.

In the embodiment of the present disclosure, the piezoelectric layer is made of any one of AlN, doped AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF, wherein the doped AlN includes any one of Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N.

In the embodiment of the present disclosure, each of the first electrode and the second electrode is made of any one of Mo, Al, Cu, Co, Ag, Ti, Pt, Ru, W, or Au.

An embodiment of the present disclosure provides an electronic device, which includes the bulk acoustic wave resonator of any one of the embodiments described above.

### BRIEF DESCRIPTION OF DRAWINGS

FIG. 1 is a schematic diagram of a structure of a back-etched bulk acoustic wave resonator.

FIG. 2 is a schematic diagram of a structure of a film bulk acoustic wave resonator.

FIG. 3 is a schematic diagram of another structure of a film bulk acoustic wave resonator.

FIG. 4 is a schematic diagram of a structure of a solid mounted bulk acoustic wave resonator.

FIG. 5 is a schematic diagram of a structure of a bulk acoustic wave resonator of a first example of an embodiment of the present disclosure.

FIG. 6 is a flow chart illustrating how to manufacture a bulk acoustic wave resonator shown in FIG. 5.

FIG. 7 is a schematic diagram of a structure of a bulk acoustic wave resonator of a second example of an embodiment of the present disclosure.

FIG. 8 is a flow chart illustrating how to manufacture a bulk acoustic wave resonator shown in FIG. 7.

FIG. 9 is a schematic diagram of a structure of a bulk acoustic wave resonator of a third example of an embodiment of the present disclosure.

FIG. 10 is a flow chart illustrating how to manufacture a bulk acoustic wave resonator shown in FIG. 9.

FIG. 11 is a schematic diagram of a structure of a bulk acoustic wave resonator of a fourth example of an embodiment of the present disclosure.

FIG. 12 is a flow chart illustrating how to manufacture a bulk acoustic wave resonator shown in FIG. 11.

FIG. 13 is a schematic diagram of a structure of a bulk acoustic wave resonator of a fifth example of an embodiment of the present disclosure.

FIG. 14 is a flow chart illustrating how to manufacture a bulk acoustic wave resonator shown in FIG. 13.

FIG. 15 is a schematic diagram of a structure of a bulk acoustic wave resonator of a sixth example of an embodiment of the present disclosure.

FIG. 16 is a flow chart illustrating how to manufacture a bulk acoustic wave resonator shown in FIG. 15.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to a physical or mechanical connection, but may include an electrical connection, whether a direct or indirect connection. The terms “upper”, “lower”, “left”, “right”, and the like are used only for indicating relative positional relationships, and when the absolute position of an object being described is changed, the relative positional relationships may also be changed accordingly.

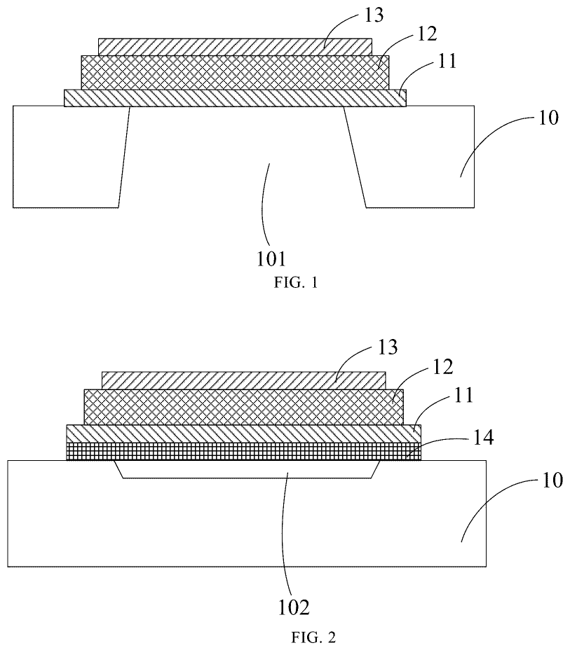

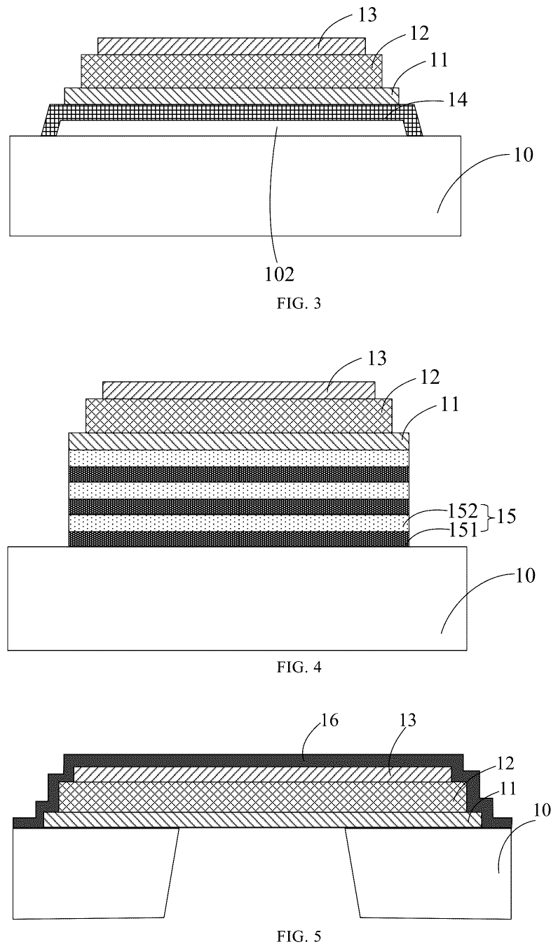

As shown in FIGS. 1 to 4, in order to reduce an insertion loss of a bulk acoustic wave resonator in a filtering process, it is necessary to limit an acoustic wave signal in a piezoelectric layer 12 between a first electrode 11 and a second electrode 13 as much as possible, to prevent the acoustic wave signal from spreading out, so that acoustic wave reflectors are usually provided on the upper and lower surfaces of the resonator. On the upper surface, an air medium with low acoustic impedance is generally used as the reflector. Depending on the acoustic wave reflectors provided on the lower surface, the bulk acoustic wave resonators are divided into three major classes, that is, a back-etched bulk acoustic wave resonator as shown in FIG. 1; a film bulk acoustic wave resonator (abbreviated as FBAR) as shown in FIGS. 2 and 3; and a solid mounted resonator (abbreviated as SMR) as shown in FIG. 4. In the FBAR, under the first electrode, a first groove 102 is formed on the base substrate 10 by etching as an air gap, and then the first electrode is supported by an isolation layer 14, as shown in FIG. 2. Alternatively, the first groove 102 is formed as the air gap in the isolation layer 14, as shown in FIG. 3. In the SMR, high acoustic impedance layers 151 and low acoustic impedance layers 152 are alternately and repeatedly stacked under the first electrode as an acoustic mirror 15. In the back-etched bulk acoustic wave resonator, under the first electrode, a first cavity 101 is formed in the base substrate 10 as an air layer by forming a cavity by deep etching back on the back of a silicon substrate.

The inventor finds that in a current bulk acoustic wave filter, the piezoelectric layer is made of C-axis aligned crystalline AlN and Sc-doped AlN having an in-plane lattice constant which increases with the increase of temperature, and an out-of-plane lattice constant decreases with the increase of temperature, which causes a propagation speed of acoustic waves to decrease. It can be known from a qualitative formula f=v/(2h) that a resonant frequency will decrease, i.e., a temperature drift (having a negative temperature coefficient of typically −30 ppm) will occur, and is detrimental to performances of a communication system; where f is a resonant frequency, v is a propagation speed of an acoustic wave in a thickness direction of the piezoelectric material, and h is a thickness of the piezoelectric material. At present, in order to solve the problem, a film with a positive temperature coefficient is generally provided in the vicinity of the piezoelectric layer, and is mainly made of SiO₂ and SiO₂ doped with F and P. The film is insulated and non-conductive, so that the piezoelectric effect and the inverse piezoelectric effect are obstructed in the vicinity of the piezoelectric layer, the effective electromechanical coupling coefficient of the resonator is reduced, the quality factor of the device is reduced, and the performance is deteriorated.

In view of the above technical problems, the embodiments of the present disclosure provide a bulk acoustic wave resonator. By applying a direct current electric field to the piezoelectric layer, a propagation speed of acoustic waves in the material of the piezoelectric layer is modulated and changed, so as to change a resonant frequency of the bulk acoustic wave resonator. When the resonant frequency of the bulk acoustic wave resonator shifts towards a low frequency direction (that is, a temperature drift occurs) due to an increase of temperature, proper direct current bias voltage is applied to two sides of the piezoelectric layer of the bulk acoustic wave resonator, so that a stable direct current electric field penetrating through the piezoelectric layer is generated, the resonant frequency of the bulk acoustic wave resonator shifts towards a high frequency direction (that is, an electric field drift occurs), and finally the resonant frequency of the bulk acoustic wave resonator is kept unchanged. Conversely, in a case of a decrease of temperature, the direct current bias voltage is reversely adjusted properly, so that the resonant frequency of the bulk acoustic wave resonator is kept unchanged.

Specific examples of a bulk acoustic wave resonator and a method for manufacturing a bulk acoustic wave resonator according to the embodiments of the present disclosure are described below with reference to specific examples.

In a first example, FIG. 5 is a schematic diagram of a structure of a bulk acoustic wave resonator of a first example of an embodiment of the present disclosure. As shown in FIG. 5, the bulk acoustic wave resonator includes a base substrate 10, and a first electrode 11, a piezoelectric layer 12, and a second electrode 13 sequentially provided on the base substrate 10. Orthographic projections of any two of the first electrode 11, the piezoelectric layer 12 and the second electrode 13 on the base substrate 10 at least partially overlap with each other. The base substrate 10 includes a first cavity 101 penetrating through the base substrate 10 in a thickness direction of the base substrate 10. In this case, a radio frequency signal enters into the bulk acoustic wave resonator, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and finally is transmitted outward from the resonator. The first cavity 101 below the bulk acoustic wave resonator and the air layer above the resonator together act as an acoustic reflector, and are configured to confine the acoustic signal within the resonator structure rather than dissipating the acoustic signal out, thereby reducing the losses of the bulk acoustic wave resonator.

When a real-time frequency compensation is performed, a direct current bias voltage is applied between the first electrode 11 and the second electrode 13, so that a direct current electric field is generated in the piezoelectric layer 12. When a direction of the direct current electric field is from the first electrode 11 to the second electrode 13, an intensity of the electric field is increased from 0 to +100 V/μm along with the increase of the direct current bias voltage, and the resonant frequency of the bulk acoustic wave resonator shifts towards a low frequency. When the direction of the direct current electric field is from the second electrode 13 to the first electrode 11, an intensity of the electric field is increased from 0 to −100 V/μm along with the increase of the direct current bias voltage, and the resonant frequency of the bulk acoustic wave resonator shifts towards a high frequency. Under the modulation of direct current electric field (in order to prevent a direct current signal from being mixed into a radio frequency signal to break down a radio frequency circuit, it is necessary to provide a DC isolator in the radio frequency circuit outside the bulk acoustic wave resonator), the resonant frequency of the bulk acoustic wave resonator is controlled to move linearly in a range from 28 ppm·f₀/(V/μm) to 58 ppm·f₀/(V/μm); a moving range of the piezoelectric material doped with AlN is greater than that of the piezoelectric material without AlN, f₀ is an initial resonant frequency without the direct current bias voltage, and V/μm is the intensity of the electric field applied to the piezoelectric layer 12. The specific use scene is that when the ambient temperature changes, a temperature drift occurs in the resonant frequency of the bulk acoustic wave resonator (the resonant frequency shifts towards a low frequency along with the increase of the temperature, and towards a high frequency along with the decrease of the temperature), so that a temperature drift occurs in a filter curve of a filter. In this case, by adjusting the direct current bias voltage applied to the piezoelectricity layer 12, the resonant frequency of the bulk acoustic wave resonator shifts towards a direction opposite to a direction of the temperature drift, so that the final effect of the unchanged resonant frequency is realized and the filter curve of the filter is ensured to be unchanged when the ambient temperature changes.

In some examples, an encapsulation layer 16 is further disposed on a side of the second electrode 13 away from the base substrate 10 to isolate moisture and oxygen and avoid device damage.

Further, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

In some examples, a material of the base substrate 10 is preferably glass, and may alternatively be Si, sapphire, SiC, GaAs, GaN, InP, BN, ZnO, GaO or the like, and a thickness of the base substrate 10 is in a range from 0.1 μm to 10 mm.

In some examples, a material of the first electrode 11 is preferably metal molybdenum Mo, which has a lattice size and a lattice structure very close to those of the material including AlN or doped AlN of the piezoelectric layer 12. The material of the first electrode 11 may alternatively be Al, Cu, Co, Ag, Ti, Pt, Ru, W, Au, or a stack or an alloy of these metals. A thickness of the first electrode 11 is in a range from 1 nm to 10 μm.

In some examples, the material of the piezoelectric layer 12 is preferably AlN and doped AlN, wherein the doped AlN is, for example, Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N. The material of the piezoelectric layer 12 may alternatively be ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF or the like. The material of the piezoelectric layer 12 may be a single piezoelectric material, or a stack of the above piezoelectric materials. A thickness of the piezoelectric layer 12 is in a range from 10 nm to 100 μm.

In some examples, a material of the second electrode 13 is preferably metal molybdenum Mo, which has a lattice size and a lattice structure very close to those of the material including AlN or doped AlN of the piezoelectric layer 12. The material of the second electrode 13 may alternatively be Al, Cu, Co, Ag, Ti, Pt, Ru, W, Au, or a stack or an alloy of these metals. A thickness of the second electrode 13 is in a range from 1 nm to 10 μm.

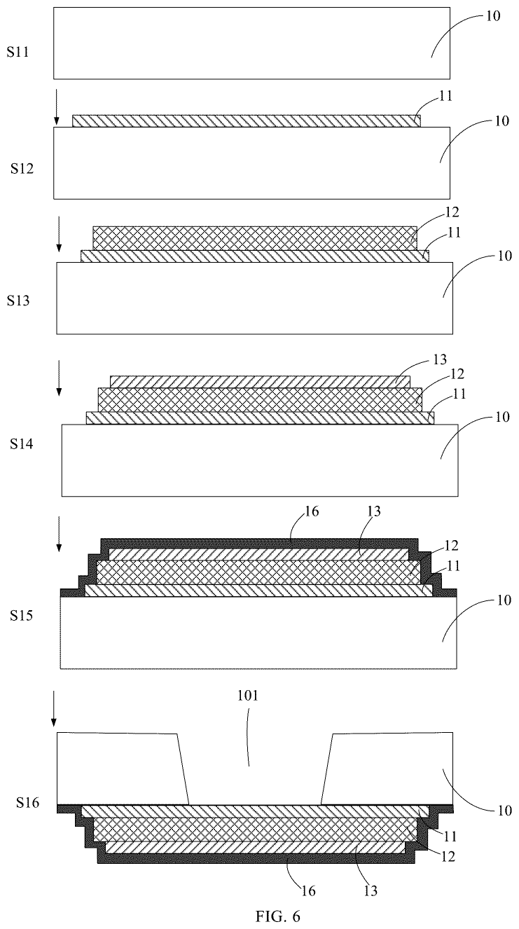

Next, a method of manufacturing the bulk acoustic wave resonator in the first example will be explained. As shown in FIG. 6, the method specifically includes the following steps S11 to S16.

The step S11 includes providing a base substrate 10.

As an example, the base substrate 10 is made of a single crystal silicon substrate, the step S11 may specifically include; firstly, performing ultrasonic cleaning on the single crystal silicon substrate with deionized water; then putting the cleaned substrate into a mixed solution of H₂SO₄:H₂O=3:1, heated to 250° C. and washed for 15 minutes; putting the substrate into the deionized water for the ultrasonic cleaning; then putting the substrate into a mixed solution of NH₄OH: H₂O=1:6, heated to 80° C. and washed for 15 minutes: taking out the substrate and putting the substrate into deionized water for washing; then, putting the substrate into a mixed solution of HCl:H₂O₂:H₂O=1:1:5, heated to 85° C. and washed for 15 minutes; taking out the substrate and putting the substrate into dilute hydrofluoric acid of HF:H₂O=1:20 for rinsing for 10 seconds to remove an oxide layer on a surface of the substrate; and finally, putting the substrate into the deionized water for the ultrasonic cleaning for 20 minutes, and drying the substrate by using an air knife to finish the whole cleaning process of the base substrate 10.

The step S12 includes forming a first electrode 11 on the base substrate 10.

When the first electrode 11 is made of a metal material, the step S12 may include depositing a first metal film on the base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation or by attaching a copper foil. Then, a photolithography process including coating photoresist (or spraying photoresist), pre-baking, exposing, developing and post-baking is performed on the first metal film. Next, an etching process is performed, preferably a wet etching process, or alternatively a dry etching process, to form a pattern including the first electrode 11. Finally, a photoresist removing process is performed to form the first electrode.

The step S13 includes forming a piezoelectric layer 12 on a side of the first electrode 11 away from the base substrate 10.

As an example, the piezoelectric layer 12 is of an AlN single-layer structure, in the step S13, a piezoelectric material layer may be formed on a side of the first electrode 11 away from the base substrate 10, and an orientation growth of the piezoelectric material layer may be performed, preferably by radio frequency magnetron sputtering (or direct current magnetron sputtering), and a target material is Al for the piezoelectric material AlN. An AlN C-axis aligned piezoelectric material layer is formed by controlling an air pressure and a temperature of Ar and N₂ and a time and temperature of post-annealing in the deposition, and preferably the growth orientation is (001). The deposition method for the piezoelectric material layer may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is then subjected to a photolithography process including coating glue (or spraying glue), pre-baking, exposing, developing and post-baking. Next, the piezoelectric material layer is etched to form a pattern of the piezoelectric layer 12; a preferred etching process may be a wet etching process or a dry etching process. Finally, a photoresist removing process is performed to form the piezoelectric layer 12.

The step S14 includes forming a second electrode 13 on a side of the piezoelectric layer 12 away from the first electrode 11.

When the second electrode 13 is made of a metal material, the step S14 may specifically include depositing a second metal film on a side of the piezoelectric layer 12 away from the first electrode 11, preferably by direct current magnetron sputtering (alternatively, radio frequency magnetron sputtering), alternatively by pulsed laser sputtering (PLD), molecular beam epitaxy (MBE), thermal evaporation, electron beam evaporation. Then, a photolithography process including coating photoresist (or spraying photoresist), pre-baking, exposing, developing and post-baking is performed on the second metal film. Next, an etching process is performed, preferably a wet etching process, or alternatively a dry etching process, to form a pattern including the second electrode 13. Finally, a photoresist removing process is performed to form the second electrode 13.

The step S15 includes forming an encapsulation layer 16 on a side of the second electrode 13 away from the base substrate 10.

As an example, the encapsulation layer 16 is made of an organic compound material. The step S15 may specifically include performing liquid coating of the organic material, such as spin coating, spraying, ink-jet printing, or transferring or the like, and then performing a heat curing process to form a pattern of the encapsulation layer 16.

The step S16 includes turning over the base substrate 10 with the above structure, and forming a first cavity 101 penetrating through the base substrate 10 in a thickness direction of the base substrate 10 by etching.

In some examples, the step S16 may include turning over the base substrate 10 with the above structure, forming a mask pattern on the back of the base substrate 10, and performing a photolithography process including coating photoresist (or spraying photoresist), pre-baking, exposing, developing and post-baking. Then, the wet etching is performed with the HF acid to form the first cavity 101, and finally, a photoresist removing process is performed.

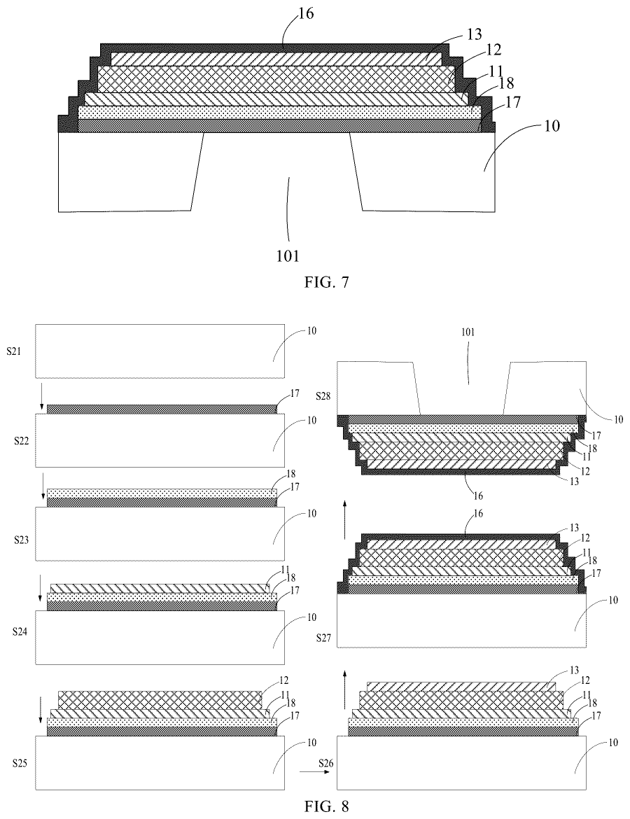

In a second example, FIG. 7 is a schematic diagram of a structure of a bulk acoustic wave resonator of a second example of an embodiment of the present disclosure. As shown in FIG. 7, the bulk acoustic wave resonator includes a base substrate 10, and a first bias resistance layer 17, a first electrical isolation layer 18, a first electrode 11, a piezoelectric layer 12, and a second electrode 13 sequentially provided on the base substrate 10. Orthographic projections of any two of the first electrode 11, the piezoelectric layer 12 and the second electrode 13 on the base substrate 10 at least partially overlap with each other. The base substrate 10 includes a first cavity 101 penetrating through the base substrate 10 in a thickness direction of the base substrate 10. In this case, a radio frequency signal enters into the bulk acoustic wave resonator, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and finally is transmitted outward from the resonator. The first cavity 101 below the bulk acoustic wave resonator and the air layer above the resonator together act as an acoustic reflector, and are configured to confine the acoustic signal within the resonator structure rather than dissipating the acoustic signal out, thereby reducing the losses of the bulk acoustic wave resonator.

When a real-time frequency compensation is performed, a direct current bias voltage is applied between the first bias resistance layer 17 and the second electrode 13, so that a direct current electric field is generated in the piezoelectric layer 12. When a direction of the direct current electric field is from the first bias resistance layer 17 to the second electrode 13, an intensity of the electric field is increased from 0 to +100 V/μm along with the increase of the direct current bias voltage, and the resonant frequency of the bulk acoustic wave resonator shifts towards a low frequency. When the direction of the direct current electric field is from the second electrode 13 to the first bias resistance layer 17, an intensity of the electric field is increased from 0 to −100 V/μm along with the increase of the direct current bias voltage, and the resonant frequency of the bulk acoustic wave resonator shifts towards a high frequency. Under the modulation of the direct current electric field (in order to prevent a direct current signal from being mixed into a radio frequency signal to break down a radio frequency circuit, it is necessary to provide a DC isolator in the radio frequency circuit outside the bulk acoustic wave resonator), the resonant frequency of the bulk acoustic wave resonator is controlled to move linearly in a range from 28 ppm·f₀/(V/μm) to 58 ppm·f₀/(V/μm); a moving range of the piezoelectric material doped with AlN is greater than that of the piezoelectric material without AlN, f₀ is an initial resonant frequency without the direct current bias voltage, and V/μm is the intensity of the electric field applied to the piezoelectric layer 12. The specific use scene is that when the ambient temperature changes, a temperature drift occurs in the resonant frequency of the bulk acoustic wave resonator (the resonant frequency shifts towards a low frequency along with the increase of the temperature, and towards a high frequency along with the decrease of the temperature), so that a temperature drift occurs in a filter curve of a filter. In this case, by adjusting the direct current bias voltage applied to the piezoelectricity layer 12, the resonant frequency of the bulk acoustic wave resonator shifts towards a direction opposite to a direction of the temperature drift, so that the final effect of the unchanged resonant frequency is realized and the filter curve of the filter is ensured to be unchanged when the ambient temperature changes.

For the second example, compared with the first example, the first bias resistance layer 17 and the first electrical isolation layer 18 are further provided between the first electrode 11 and the base substrate 10, so as to isolate a direct current signal from a radio frequency signal in a lower half part of the bulk acoustic wave resonator.

In some examples, an encapsulation layer 16 is further disposed on a side of the second electrode 13 away from the base substrate 10 to isolate moisture and oxygen and avoid device damage.

Further, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

In some examples, a material of the base substrate 10 is preferably glass, and may alternatively be Si, sapphire, SiC, GaAs, GaN, InP, BN, ZnO, GaO or the like, and a thickness of the base substrate 10 is in a range from 0.1 μm to 10 mm.

In some examples, a material of the first bias resistance layer 17 is a conductive material having a high resistivity, preferably ITO, or alternatively IZO, ZnO, IGO, IGZO, W, Mn, Cr, Ti, Ni, constantan alloy, manganin alloy, nichrome alloy, iron-chromium-aluminum alloy, or the like. The first bias resistance layer 17 may be a single material or a stack of the above materials. A thickness of the first bias resistance layer 17 is in a range from 1 nm to 10 μm.

In some embodiments, the first electrical isolation layer 18 is made of an insulating material, preferably Si₃N₄, or alternatively SiO₂, Al₂O₃, AlN, BN, or the like. The first electrical isolation layer 18 may be a single material or a stack of the above materials. A thickness of the first electrical isolation layer 18 is in a range from 1 nm to 10 μm.

In some examples, a material of the first electrode 11 is preferably metal molybdenum, which has a lattice size and a lattice structure very close to those of the material including AlN or doped AlN of the piezoelectric layer 12. The material of the first electrode 11 may alternatively be Al, Cu, Co, Ag, Ti, Pt, Ru, W, Au, or a stack or an alloy of these metals. A thickness of the first electrode 11 is in a range from 1 nm to 10 μm.

In some examples, the material of the piezoelectric layer 12 is preferably AlN and doped AlN, wherein the doped AlN is, for example, Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N. The material of the piezoelectric layer 12 may alternatively be ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF or the like. The material of the piezoelectric layer 12 may be a single piezoelectric material, or a stack of the above piezoelectric materials. A thickness of the piezoelectric layer 12 is in a range from 10 nm to 100 μm.

In some examples, a material of the second electrode 13 is preferably metal molybdenum, which has a lattice size and a lattice structure very close to those of the material including AlN or doped AlN of the piezoelectric layer 12. The material of the second electrode 13 may alternatively be Al, Cu, Co, Ag, Ti, Pt, Ru, W, Au, or a stack or an alloy of these metals. A thickness of the second electrode 13 is in a range from 1 nm to 10 μm.

Next, a method for manufacturing the bulk acoustic wave resonator in the second example will be explained. As shown in FIG. 8, the method specifically includes the following steps S21 to S28.

The step S21 includes providing a base substrate 10.

As an example, the base substrate 10 is made of a single crystal silicon substrate, the step S21 may specifically include; firstly, performing ultrasonic cleaning on the single crystal silicon substrate with deionized water; then putting the cleaned substrate into a mixed solution of H₂SO₄:H₂O=3:1, heated to 250° C. and washed for 15 minutes; putting the substrate into the deionized water for the ultrasonic cleaning; then putting the substrate into a mixed solution of NH₄OH:H₂O=1:6, heated to 80° C. and washed for 15 minutes; taking out the substrate and putting the substrate into deionized water for washing; then, putting the substrate into a mixed solution of HCl:H₂O₂: H₂O=1:1:5, heated to 85° C. and washed for 15 minutes; taking out the substrate and putting the substrate into dilute hydrofluoric acid of HF:H₂O=1:20 for rinsing for 10 seconds to remove an oxide layer on a surface of the substrate; and finally, putting the substrate into the deionized water for the ultrasonic cleaning for 20 minutes, and drying the substrate by using an air knife to finish the whole cleaning process of the base substrate 10.

The step S22 includes forming a first bias resistance layer 17 on the base substrate 10.

Specifically, in the step S22, a conductive material film having a high resistivity may be deposited, preferably by radio frequency magnetron sputtering (alternatively, direct current magnetron sputtering), alternatively by pulsed laser sputtering (PLD), molecular beam epitaxy (MBE), thermal evaporation, electron beam evaporation or by attaching a metal foil or an alloy foil. Then, a photolithography process including coating photoresist (or spraying photoresist), pre-baking, exposing, developing and post-baking is performed on the conductive material film. Next, an etching process is performed, preferably a wet etching process, or alternatively a dry etching process, thereby forming the first bias resistance layer 17.

The step S23 includes forming a first electrical isolation layer 18 on a side of the first bias resistance layer 17 away from the base substrate 10.

Specifically, the step S23 may include depositing an electrical insulating material, by radio frequency magnetron sputtering, pulsed laser sputtering (PLD), atomic layer deposition (ALD), or plasma chemical vapor deposition (PECVD). Then, a photolithography process including coating photoresist (or spraying photoresist), pre-baking, exposing, developing and post-baking is performed on the electrical insulating material. Next, an etching process is performed, preferably a wet etching process, or alternatively a dry etching process, thereby forming the first electrical isolation layer 18.

The step S24 includes forming a first electrode 11 on a side of the first electrical isolation layer 18 away from the base substrate 10.

When the first electrode 11 is made of a metal material, the step S24 may include depositing a first metal film on the base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation or by attaching a copper foil. Then, a photolithography process including coating photoresist (or spraying photoresist), pre-baking, exposing, developing and post-baking is performed on the first metal film. Next, an etching process is performed, preferably a wet etching process, or alternatively a dry etching process, to form a pattern including the first electrode 11. Finally, a photoresist removing process is performed to form the first electrode.

The step S25 includes forming a piezoelectric layer 12 on a side of the first electrode 11 away from the base substrate 10.

As an example, the piezoelectric layer 12 is of an AlN single-layer structure, in the step S25, a piezoelectric material layer may be formed on a side of the first electrode 11 away from the base substrate 10, and an orientation growth of the piezoelectric material layer may be performed, preferably by radio frequency magnetron sputtering (or direct current magnetron sputtering), and a target material is Al for the piezoelectric material AlN. An AlN C-axis aligned piezoelectric material layer is formed by controlling an air pressure and a temperature of Ar and N₂ and a time and temperature of post-annealing in the deposition, and preferably the growth orientation is (001). The deposition method for the piezoelectric material layer may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is then subjected to a photolithography process including coating glue (or spraying glue), pre-baking, exposing, developing and post-baking. Next, the piezoelectric material layer is etched to form a pattern of the piezoelectric layer 12; a preferred etching process may be a wet etching process or a dry etching process. Finally, a photoresist removing process is performed to form the piezoelectric layer 12.

The step S26 includes forming a second electrode 13 on a side of the piezoelectric layer 12 away from the first electrode 11.

When the second electrode 13 is made of a metal material, the step S26 may specifically include depositing a second metal film on a side of the piezoelectric layer 12 away from the first electrode 11, preferably by direct current magnetron sputtering (alternatively, radio frequency magnetron sputtering), alternatively by pulsed laser sputtering (PLD), molecular beam epitaxy (MBE), thermal evaporation, electron beam evaporation. Then, a photolithography process including coating photoresist (or spraying photoresist), pre-baking, exposing, developing and post-baking is performed on the second metal film. Next, an etching process is performed, preferably a wet etching process, or alternatively a dry etching process, to form a pattern including the second electrode 13. Finally, a photoresist removing process is performed to form the second electrode 13.

The step S27 includes forming an encapsulation layer 16 on a side of the second electrode 13 away from the base substrate 10.

As an example, the encapsulation layer 16 is made of an organic compound material. The step S27 may specifically include performing liquid coating of the organic material, such as spin coating, spraying, ink-jet printing, or transferring or the like, and then performing a heat curing process to form a pattern of the encapsulation layer 16.

The step S28 includes turning over the base substrate 10 with the above structure, and forming a first cavity 101 penetrating through the base substrate 10 in a thickness direction of the base substrate 10 by etching.

In some examples, the step S28 may include turning over the base substrate 10 with the above structure, forming a mask pattern on the back of the base substrate 10, and performing a photolithography process including coating photoresist (or spraying photoresist), pre-baking, exposing, developing and post-baking. Then, the wet etching is performed with the HF acid to form the first cavity 101, and finally, a photoresist removing process is performed.

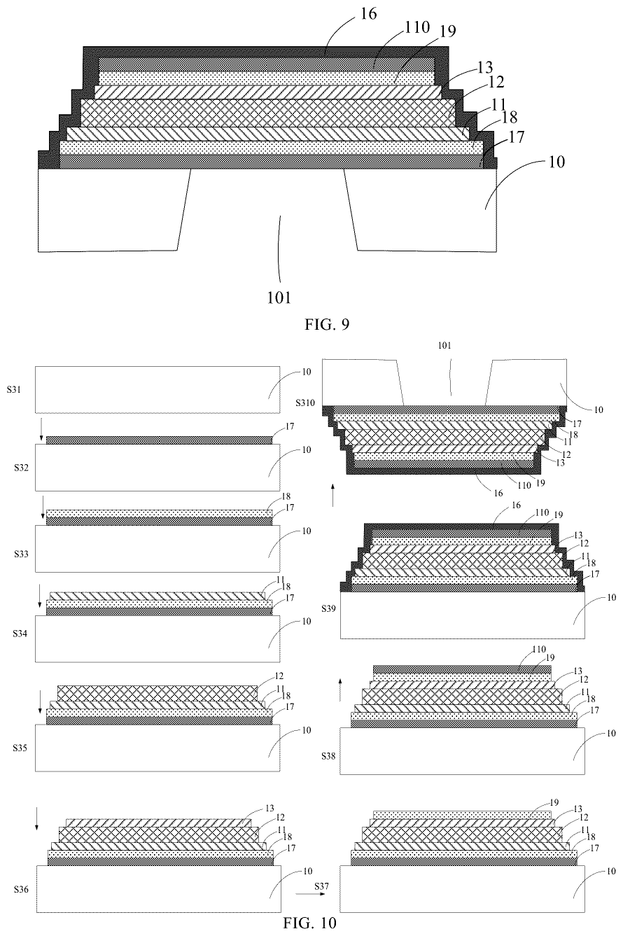

In a third example: FIG. 9 is a schematic diagram of a structure of a bulk acoustic wave resonator of a third example of an embodiment of the present disclosure. As shown in FIG. 9, the bulk acoustic wave resonator includes a base substrate 10, and a first bias resistance layer 17, a first electrical isolation layer 18, a first electrode 11, a piezoelectric layer 12, a second electrode 13, a second electrical isolation layer 19, and a second bias resistance layer 110 sequentially provided on the base substrate 10. Orthographic projections of any two of the first electrode 11, the piezoelectric layer 12 and the second electrode 13 on the base substrate 10 at least partially overlap with each other. The base substrate 10 includes a first cavity 101 penetrating through the base substrate 10 in a thickness direction of the base substrate 10. In this case, a radio frequency signal enters into the bulk acoustic wave resonator, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and finally is transmitted outward from the resonator. The first cavity 101 below the bulk acoustic wave resonator and the air layer above the resonator together act as an acoustic reflector, and are configured to confine the acoustic signal within the resonator structure rather than dissipating the acoustic signal out, thereby reducing the losses of the bulk acoustic wave resonator.

When a real-time frequency compensation is performed, a direct current bias voltage is applied between the first bias resistance layer 17 and the second bias resistance layer 110, so that a direct current electric field is generated in the piezoelectric layer 12. When a direction of the direct current electric field is from the first bias resistance layer 17 to the second bias resistance layer 110, an intensity of the electric field is increased from 0 to +100 V/μm along with the increase of the direct current bias voltage, and the resonant frequency of the bulk acoustic wave resonator shifts towards a low frequency. When the direction of the direct current electric field is from the second bias resistance layer 110 to the first bias resistance layer 17, an intensity of the electric field is increased from 0 to −100 V/μm along with the increase of the direct current bias voltage, and the resonant frequency of the bulk acoustic wave resonator shifts towards a high frequency. Under the modulation of direct current electric field, the resonant frequency of the bulk acoustic wave resonator is controlled to move linearly in a range from 28 ppm·f₀/(V/μm) to 58 ppm·f₀/(V/μm); wherein a moving range of the piezoelectric material doped with AlN is greater than that of the piezoelectric material without AlN, f₀ is an initial resonant frequency without the direct current bias voltage, and V/μm is the intensity of the electric field applied to the piezoelectric layer 12. The specific use scene is that when the ambient temperature changes, a temperature drift occurs in the resonant frequency of the bulk acoustic wave resonator (the resonant frequency shifts towards a low frequency along with the increase of the temperature, and towards a high frequency along with the decrease of the temperature), so that a temperature drift occurs in a filter curve of a filter. In this case, by adjusting the direct current bias voltage applied to the piezoelectricity layer 12, the resonant frequency of the bulk acoustic wave resonator shifts towards a direction opposite to a direction of the temperature drift, so that the final effect of the unchanged resonant frequency is realized and the filter curve of the filter is ensured to be unchanged when the ambient temperature changes.

For the third example, compared with the second example, the second electrical isolation layer 19 and the second bias resistance layer 110 are further provided on the second electrode 13, so as to completely isolate a direct current signal from a radio frequency signal on two opposite sides of the bulk acoustic wave resonator. In this way, it is not necessary to provide a DC isolator outside a piezoelectric filter.

In some examples, an encapsulation layer 16 is further disposed on a side of the second electrode 13 away from the base substrate 10 to isolate moisture and oxygen and avoid device damage.

Further, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

In some examples, a material of the base substrate 10 is preferably glass, and may alternatively be Si, sapphire, SiC, GaAs, GaN, InP, BN, ZnO, GaO or the like, and a thickness of the base substrate 10 is in a range from 0.1 μm to 10 mm.

In some examples, a material of each of the first bias resistance layer 17 and the second bias resistance layer 110 is a conductive material having a high resistivity, preferably ITO, or alternatively IZO, ZnO, IGO, IGZO, W, Mn, Cr, Ti, Ni, constantan alloy, manganin alloy, nichrome alloy, iron-chromium-aluminum alloy, or the like. The first bias resistance layer 17 may be a single material or a stack of the above materials. A thickness of the first bias resistance layer 17 is in a range from 1 nm to 10 μm.

In some embodiments, each of the first electrical isolation layer 18 and the second electrical isolation layer 19 is made of an insulating material, preferably Si₃N₄, or alternatively SiO₂, Al₂O₃, AlN, BN, or the like. The first electrical isolation layer 18 may be a single material or a stack of the above materials. A thickness of the first electrical isolation layer 18 is in a range from 1 nm to 10 μm.

In some examples, a material of the first electrode 11 is preferably metal molybdenum, which has a lattice size and a lattice structure very close to those of the material including AlN or doped AlN of the piezoelectric layer 12. The material of the first electrode 11 may alternatively be Al, Cu, Co, Ag, Ti, Pt, Ru, W, Au, or a stack or an alloy of these metals. A thickness of the first electrode 11 is in a range from 1 nm to 10 μm.

In some examples, the material of the piezoelectric layer 12 is preferably AlN and doped AlN, wherein the doped AlN is, for example, Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N. The material of the piezoelectric layer 12 may alternatively be ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF or the like. The material of the piezoelectric layer 12 may be a single piezoelectric material, or a stack of the above piezoelectric materials. A thickness of the piezoelectric layer 12 is in a range from 10 nm to 100 μm.

In some examples, a material of the second electrode 13 is preferably metal molybdenum, which has a lattice size and a lattice structure very close to those of the material including AlN or doped AlN of the piezoelectric layer 12. The material of the second electrode 13 may alternatively be Al, Cu, Co, Ag, Ti, Pt, Ru, W, Au, or a stack or an alloy of these metals. A thickness of the second electrode 13 is in a range from 1 nm to 10 μm.

Next, a method of manufacturing the bulk acoustic wave resonator in the third example will be explained. As shown in FIG. 10, the method specifically includes the following steps S31 to S310.

The step S31 includes providing a base substrate 10.

As an example, the base substrate 10 is made of a single crystal silicon substrate, the step S31 may specifically include; firstly, performing ultrasonic cleaning on the single crystal silicon substrate with deionized water; then putting the cleaned substrate into a mixed solution of H₂SO₄:H₂O=3:1, heated to 250° C. and washed for 15 minutes; putting the substrate into the deionized water for the ultrasonic cleaning; then putting the substrate into a mixed solution of NH₄OH:H₂O=1:6, heated to 80° C. and washed for 15 minutes; taking out the substrate and putting the substrate into deionized water for washing; then, putting the substrate into a mixed solution of HCl:H₂O₂:H₂O=1:1:5, heated to 85° C. and washed for 15 minutes; taking out the substrate and putting the substrate into dilute hydrofluoric acid of HF:H₂O=1:20 for rinsing for 10 seconds to remove an oxide layer on a surface of the substrate; and finally, putting the substrate into the deionized water for the ultrasonic cleaning for 20 minutes, and drying the substrate by using an air knife to finish the whole cleaning process of the base substrate 10.

The step S32 includes forming a first bias resistance layer 17 on the base substrate 10.

Specifically, in the step S32, a conductive material film having a high resistivity may be deposited, preferably by radio frequency magnetron sputtering (alternatively, direct current magnetron sputtering), alternatively by pulsed laser sputtering (PLD), molecular beam epitaxy (MBE), thermal evaporation, electron beam evaporation or by attaching a metal foil or an alloy foil. Then, a photolithography process including coating photoresist (or spraying photoresist), pre-baking, exposing, developing and post-baking is performed on the conductive material film. Next, an etching process is performed, preferably a wet etching process, or alternatively a dry etching process, thereby forming the first bias resistance layer 17.

The step S33 includes forming a first electrical isolation layer 18 on a side of the first bias resistance layer 17 away from the base substrate 10.

Specifically, the step S33 may include depositing an electrical insulating material, by radio frequency magnetron sputtering, pulsed laser sputtering (PLD), atomic layer deposition (ALD), or plasma chemical vapor deposition (PECVD). Then, a photolithography process including coating photoresist (or spraying photoresist), pre-baking, exposing, developing and post-baking is performed on the electrical insulating material. Next, an etching process is performed, preferably a wet etching process, or alternatively a dry etching process, thereby forming the first electrical isolation layer 18.

The step S34 includes forming a first electrode 11 on a side of the first electrical isolation layer 18 away from the base substrate 10.

When the first electrode 11 is made of a metal material, the step S34 may include depositing a first metal film on the base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation or by attaching a copper foil. Then, a photolithography process including coating photoresist (or spraying photoresist), pre-baking, exposing, developing and post-baking is performed on the first metal film. Next, an etching process is performed. preferably a wet etching process, or alternatively a dry etching process, to form a pattern including the first electrode 11. Finally, a photoresist removing process is performed to form the first electrode.

The step S35 includes forming a piezoelectric layer 12 on a side of the first electrode 11 away from the base substrate 10.

As an example, the piezoelectric layer 12 is of an AlN single-layer structure, in the step S35, a piezoelectric material layer may be formed on a side of the first electrode 11 away from the base substrate 10, and an orientation growth of the piezoelectric material layer may be performed, preferably by radio frequency magnetron sputtering (or direct current magnetron sputtering), and a target material is Al for the piezoelectric material AlN. An AlN C-axis aligned piezoelectric material layer is formed by controlling an air pressure and a temperature of Ar and N₂ and a time and temperature of post-annealing in the deposition, and preferably the growth orientation is (001). The deposition method for the piezoelectric material layer may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is then subjected to a photolithography process including coating glue (or spraying glue), pre-baking, exposing, developing and post-baking. Next, the piezoelectric material layer is etched to form a pattern of the piezoelectric layer 12; a preferred etching process may be a wet etching process or a dry etching process. Finally, a photoresist removing process is performed to form the piezoelectric layer 12.

The step S36 includes forming a second electrode 13 on a side of the piezoelectric layer 12 away from the first electrode 11.

When the second electrode 13 is made of a metal material, the step S36 may specifically include depositing a second metal film on a side of the piezoelectric layer 12 away from the first electrode 11, preferably by direct current magnetron sputtering (alternatively, radio frequency magnetron sputtering), alternatively by pulsed laser sputtering (PLD), molecular beam epitaxy (MBE), thermal evaporation, electron beam evaporation. Then, a photolithography process including coating photoresist (or spraying photoresist), pre-baking, exposing, developing and post-baking is performed on the second metal film. Next, an etching process is performed, preferably a wet etching process, or alternatively a dry etching process, to form a pattern including the second electrode 13. Finally, a photoresist removing process is performed to form the second electrode 13.

The step S37 includes forming a second electrical isolation layer 19 on a side of the second electrode 13 away from the base substrate 10.

The second electrical isolation layer 19 is formed by the same process as the first electrical isolation layer 18, and therefore, the description thereof is omitted.

The step S38 includes forming a second bias resistance layer 110 on a side of the second electrical isolation layer 19 away from the base substrate 10.

The second bias resistance layer 110 is formed by the same process as the first bias resistance layer 17, and therefore, the description thereof is omitted.

The step S39 includes forming an encapsulation layer 16 on a side of the second bias resistance layer 110 away from the base substrate 10.

As an example, the encapsulation layer 16 is made of an organic compound material. The step S39 may specifically include performing liquid coating of the organic material, such as spin coating, spraying, ink-jet printing, or transferring or the like, and then performing a heat curing process to form a pattern of the encapsulation layer 16.

The step S310 includes turning over the base substrate 10 with the above structure, and forming a first cavity 101 penetrating through the base substrate 10 in a thickness direction of the base substrate 10 by etching.

In some examples, the step S310 may include turning over the base substrate 10 with the above structure, forming a mask pattern on the back of the base substrate 10, and performing a photolithography process including coating photoresist (or spraying photoresist), pre-baking, exposing, developing and post-baking. Then, the wet etching is performed with the HF acid to form the first cavity 101, and finally, a photoresist removing process is performed.

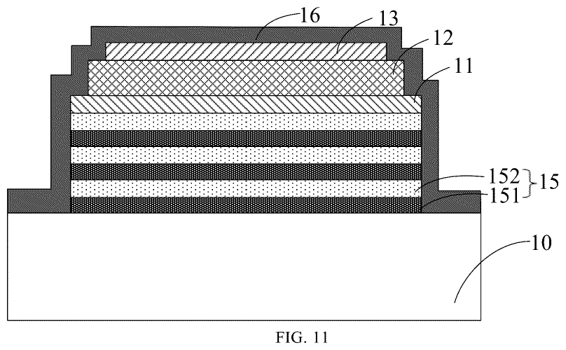

In a fourth example: FIG. 11 is a schematic diagram of a structure of a bulk acoustic wave resonator of a fourth example of an embodiment of the present disclosure. As shown in FIG. 11, the bulk acoustic wave resonator includes a base substrate 10, and at least one acoustic mirror structure 15, a first electrode 11, a piezoelectric layer 12, and a second electrode 13 sequentially provided on the base substrate 10. Orthographic projections of any two of the first electrode 11, the piezoelectric layer 12 and the second electrode 13 on the base substrate 10 at least partially overlap with each other. Each acoustic mirror structure 15 includes a first sub-structure and a second sub-structure sequentially arranged along a direction away from the base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152. In this case, a radio frequency signal enters into the bulk acoustic wave resonator, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and finally is transmitted outward from the resonator. The first cavity 101 below the bulk acoustic wave resonator and the air layer above the resonator together act as an acoustic reflector, and are configured to confine the acoustic signal within the resonator structure rather than dissipating the acoustic signal out, thereby reducing the losses of the bulk acoustic wave resonator.

When a real-time frequency compensation is performed, a direct current bias voltage is applied between the first electrode 11 and the second electrode 13, so that a direct current electric field is generated in the piezoelectric layer 12. When a direction of the direct current electric field is from the first electrode 11 to the second electrode 13, an intensity of the electric field is increased from 0 to +100 V/μm along with the increase of the direct current bias voltage, and the resonant frequency of the bulk acoustic wave resonator shifts towards a low frequency. When the direction of the direct current electric field is from the second electrode 13 to the first electrode 11, an intensity of the electric field is increased from 0 to −100 V/μm along with the increase of the direct current bias voltage, and the resonant frequency of the bulk acoustic wave resonator shifts towards a high frequency. Under the modulation of the direct current electric field (in order to prevent a direct current signal from being mixed into a radio frequency signal to break down a radio frequency circuit, it is necessary to provide a DC isolator in the radio frequency circuit outside the bulk acoustic wave resonator), the resonant frequency of the bulk acoustic wave resonator is controlled to move linearly in a range from 28 ppm·f₀/(V/μm) to 58 ppm·f₀/(V/μm); a moving range of the piezoelectric material doped with AlN is greater than that of the piezoelectric material without AlN, fₒ is an initial resonant frequency without the direct current bias voltage, and V/μm is the intensity of the electric field applied to the piezoelectric layer 12. The specific use scene is that when the ambient temperature changes, a temperature drift occurs in the resonant frequency of the bulk acoustic wave resonator (the resonant frequency shifts towards a low frequency along with the increase of the temperature, and towards a high frequency along with the decrease of the temperature), so that a temperature drift occurs in a filter curve of a filter. In this case, by adjusting the direct current bias voltage applied to the piezoelectricity layer 12, the resonant frequency of the bulk acoustic wave resonator shifts towards a direction opposite to a direction of the temperature drift, so that the final effect of the unchanged resonant frequency is realized and the filter curve of the filter is ensured to be unchanged when the ambient temperature changes.

In some examples, an encapsulation layer 16 is further disposed on a side of the second electrode 13 away from the base substrate 10 to isolate moisture and oxygen and avoid device damage.

Further, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

In some examples, a material of the base substrate 10 is preferably glass, and may alternatively be Si, sapphire, SiC, GaAs, GaN, InP, BN, ZnO, GaO or the like, and a thickness of the base substrate 10 is in a range from 0.1 μm to 10 mm.

In some examples, the at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low . . . or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta, Ti, Cu, Ni, Zn, Al, Al₂O₃, Ag, etc., and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

In some examples, a material of the first electrode 11 is preferably metal molybdenum, which has a lattice size and a lattice structure very close to those of the material including AlN or doped AlN of the piezoelectric layer 12. The material of the first electrode 11 may alternatively be Al, Cu, Co, Ag, Ti, Pt, Ru, W, Au, or a stack or an alloy of these metals. A thickness of the first electrode 11 is in a range from 1 nm to 10 μm.

In some examples, the material of the piezoelectric layer 12 is preferably AlN and doped AlN, wherein the doped AlN is, for example, Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N. The material of the piezoelectric layer 12 may alternatively be ZnO, PZT, GaN, InN, CdS. CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF or the like. The material of the piezoelectric layer 12 may be a single piezoelectric material, or a stack of the above piezoelectric materials. A thickness of the piezoelectric layer 12 is in a range from 10 nm to 100 μm.

In some examples, a material of the second electrode 13 is preferably metal molybdenum, which has a lattice size and a lattice structure very close to those of the material including AlN or doped AlN of the piezoelectric layer 12. The material of the second electrode 13 may alternatively be Al, Cu, Co, Ag, Ti, Pt, Ru, W, Au, or a stack or an alloy of these metals. A thickness of the second electrode 13 is in a range from 1 nm to 10 μm.

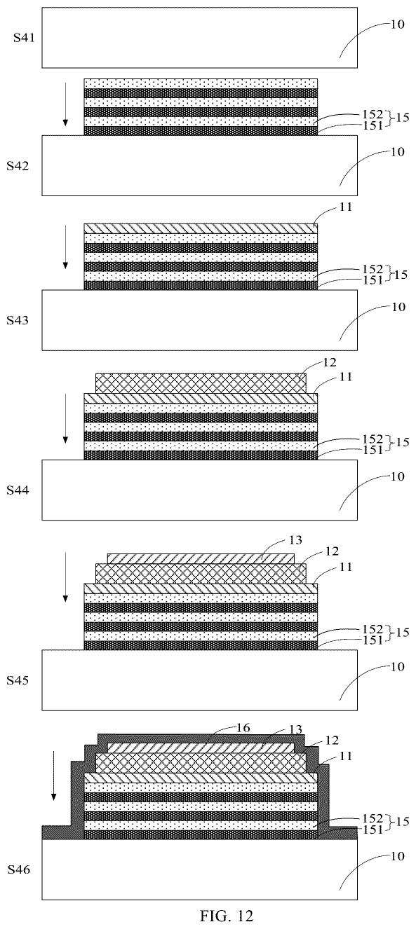

Next, a method for manufacturing the bulk acoustic wave resonator in the fourth example will be explained. As shown in FIG. 12, the method specifically includes the following steps S41 to S46.

The step S41 includes providing a base substrate 10.

As an example, the base substrate 10 is made of a single crystal silicon substrate, the step S41 may specifically include; firstly, performing ultrasonic cleaning on the single crystal silicon substrate with deionized water; then putting the cleaned substrate into a mixed solution of H₂SO₄:H₂O=3:1, heated to 250° C. and washed for 15 minutes; putting the substrate into the deionized water for the ultrasonic cleaning; then putting the substrate into a mixed solution of NH₄OH:H₂O=1:6, heated to 80° C. and washed for 15 minutes; taking out the substrate and putting the substrate into deionized water for washing; then, putting the substrate into a mixed solution of HCl:H₂O₂:H₂O=1:1:5, heated to 85° C. and washed for 15 minutes; taking out the substrate and putting the substrate into dilute hydrofluoric acid of HF:H₂O=1:20 for rinsing for 10 seconds to remove an oxide layer on a surface of the substrate; and finally, putting the substrate into the deionized water for the ultrasonic cleaning for 20 minutes, and drying the substrate by using an air knife to finish the whole cleaning process of the base substrate 10.

The step S42 includes forming at least one mirror structure 15 on the base substrate 10.

The step S42 may specifically include; the following steps (a) and (b). In the step (a), a film material for a high acoustic impedance layer 151 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

The step S43 includes forming a first electrode 11 on the base substrate 10.

When the first electrode 11 is made of a metal material, the step S43 may include depositing a first metal film on the base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation or by attaching a copper foil. Then, a photolithography process including coating photoresist (or spraying photoresist), pre-baking, exposing, developing and post-baking is performed on the first metal film. Next, an etching process is performed, preferably a wet etching process, or alternatively a dry etching process, to form a pattern including the first electrode 11. Finally, a photoresist removing process is performed to form the first electrode.

The step S44 includes forming a piezoelectric layer 12 on a side of the first electrode 11 away from the base substrate 10.

As an example, the piezoelectric layer 12 is of an AlN single-layer structure, in the step S44, a piezoelectric material layer may be formed on a side of the first electrode 11 away from the base substrate 10, and an orientation growth of the piezoelectric material layer may be performed, preferably by radio frequency magnetron sputtering (or direct current magnetron sputtering), and a target material is Al for the piezoelectric material AlN. An AlN C-axis aligned piezoelectric material layer is formed by controlling an air pressure and a temperature of Ar and N₂ and a time and temperature of post-annealing in the deposition, and preferably the growth orientation is (001). The deposition method for the piezoelectric material layer may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is then subjected to a photolithography process including coating glue (or spraying glue), pre-baking, exposing, developing and post-baking. Next, the piezoelectric material layer is etched to form a pattern of the piezoelectric layer 12; a preferred etching process may be a wet etching process or a dry etching process. Finally, a photoresist removing process is performed to form the piezoelectric layer 12.

The step S45 includes forming a second electrode 13 on a side of the piezoelectric layer 12 away from the first electrode 11.

When the second electrode 13 is made of a metal material, the step S45 may specifically include depositing a second metal film on a side of the piezoelectric layer 12 away from the first electrode 11, preferably by direct current magnetron sputtering (alternatively, radio frequency magnetron sputtering), alternatively by pulsed laser sputtering (PLD), molecular beam epitaxy (MBE), thermal evaporation, electron beam evaporation. Then, a photolithography process including coating photoresist (or spraying photoresist), pre-baking, exposing, developing and post-baking is performed on the second metal film. Next, an etching process is performed, preferably a wet etching process, or alternatively a dry etching process, to form a pattern including the second electrode 13. Finally, a photoresist removing process is performed to form the second electrode 13.

The step S46 includes forming an encapsulation layer 16 on a side of the second electrode 13 away from the base substrate 10.

As an example, the encapsulation layer 16 is made of an organic compound material. The step S46 may specifically include performing liquid coating of the organic material, such as spin coating, spraying, ink-jet printing, or transferring or the like, and then performing a heat curing process to form a pattern of the encapsulation layer 16.

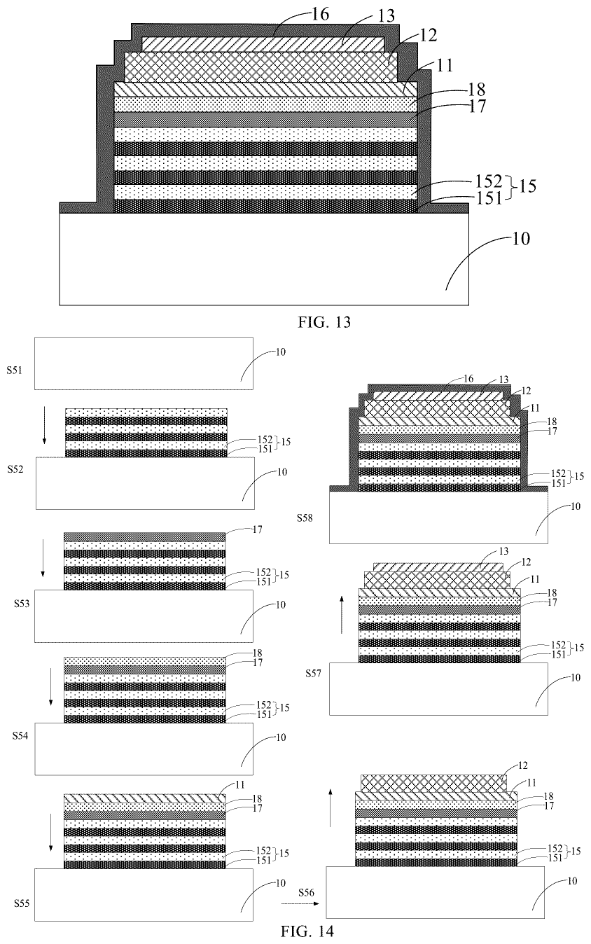

In a fifth example: FIG. 13 is a schematic diagram of a structure of a bulk acoustic wave resonator of a fifth example of an embodiment of the present disclosure. As shown in FIG. 13, the bulk acoustic wave resonator includes a base substrate 10, and at least one acoustic mirror structure 15, a first bias resistance layer 17, a first electrical isolation layer 18, a first electrode 11, a piezoelectric layer 12, and a second electrode 13 sequentially provided on the base substrate 10. Orthographic projections of any two of the first electrode 11, the piezoelectric layer 12 and the second electrode 13 on the base substrate 10 at least partially overlap with each other. Each acoustic mirror structure 15 includes a first sub-structure and a second sub-structure sequentially arranged along a direction away from the base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152. In this case, a radio frequency signal enters into the bulk acoustic wave resonator, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and finally is transmitted outward from the resonator. The first cavity 101 below the bulk acoustic wave resonator and the air layer above the resonator together act as an acoustic reflector, and are configured to confine the acoustic signal within the resonator structure rather than dissipating the acoustic signal out, thereby reducing the loss of the bulk acoustic wave resonator.

When a real-time frequency compensation is performed, a direct current bias voltage is applied between the first bias resistance layer 17 and the second electrode 13, so that a direct current electric field is generated in the piezoelectric layer 12. When a direction of the direct current electric field is from the first bias resistance layer 17 to the second electrode 13, an intensity of the electric field is increased from 0 to +100 V/μm along with the increase of the direct current bias voltage, and the resonant frequency of the bulk acoustic wave resonator shifts towards a low frequency. When the direction of the direct current electric field is from the second electrode 13 to the first bias resistance layer 17, an intensity of the electric field is increased from 0 to −100 V/μm along with the increase of the direct current bias voltage, and the resonant frequency of the bulk acoustic wave resonator shifts towards a high frequency. Under the modulation of direct current electric field (in order to prevent a direct current signal from being mixed into a radio frequency signal to break down a radio frequency circuit, it is necessary to provide a DC isolator in the radio frequency circuit outside the bulk acoustic wave resonator), the resonant frequency of the bulk acoustic wave resonator is controlled to move linearly in a range from 28 ppm·f₀/(V/μm) to 58 ppm·f₀/(V/μm); wherein a moving range of the piezoelectric material doped with AlN is greater than that of the piezoelectric material without AlN, f₀ is an initial resonant frequency without the direct current bias voltage, and V/μm is the intensity of the electric field applied to the piezoelectric layer 12. The specific use scene is that when the ambient temperature changes, a temperature drift occurs in the resonant frequency of the bulk acoustic wave resonator (the resonant frequency shifts towards a low frequency along with the increase of the temperature, and towards a high frequency along with the decrease of the temperature), so that a temperature drift occurs in a filter curve of a filter. In this case, by adjusting the direct current bias voltage applied to the piezoelectricity layer 12, the resonant frequency of the bulk acoustic wave resonator shifts towards a direction opposite to a direction of the temperature drift, so that the final effect of the unchanged resonant frequency is realized and the filter curve of the filter is ensured to be unchanged when the ambient temperature changes.

For the fifth example, compared with the fourth example, the first bias resistance layer 17 and the first electrical isolation layer 18 are further provided between the first electrode 11 and the at least one acoustic mirror structure 15, so as to isolate a direct current signal from a radio frequency signal in a lower half part of the bulk acoustic wave resonator.

In some examples, an encapsulation layer 16 is further disposed on a side of the second electrode 13 away from the base substrate 10 to isolate moisture and oxygen and avoid device damage.

Further, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

In some examples, a material of the base substrate 10 is preferably glass, and may alternatively be Si, sapphire, SiC, GaAs, GaN, InP, BN, ZnO, GaO or the like, and a thickness of the base substrate 10 is in a range from 0.1 μm to 10 mm.

In some examples, the at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low . . . or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta. Ti, Cu, Ni, Zn, Al, Al₂O₃, Ag, etc., and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

In some examples, a material of the first bias resistance layer 17 is a conductive material having a high resistivity, preferably ITO, or alternatively IZO, ZnO, IGO, IGZO, W, Mn, Cr, Ti, Ni, constantan alloy, manganin alloy, nichrome alloy, iron-chromium-aluminum alloy, or the like. The first bias resistance layer 17 may be a single material or a stack of the above materials. A thickness of the first bias resistance layer 17 is in a range from 1 nm to 10 μm.

In some embodiments, the first electrical isolation layer 18 is made of an insulating material, preferably Si₃N₄, or alternatively SiO₂, Al₂O₃, AlN, BN, or the like. The first electrical isolation layer 18 may be a single material or a stack of the above materials. A thickness of the first electrical isolation layer 18 is in a range from 1 nm to 10 μm.

In some examples, a material of the first electrode 11 is preferably metal molybdenum, which has a lattice size and a lattice structure very close to those of the material including AlN or doped AlN of the piezoelectric layer 12. The material of the first electrode 11 may alternatively be Al, Cu, Co, Ag, Ti, Pt, Ru, W, Au, or a stack or an alloy of these metals. A thickness of the first electrode 11 is in a range from 1 nm to 10 μm.

In some examples, the material of the piezoelectric layer 12 is preferably AlN and doped AlN, wherein the doped AlN is, for example, Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N. The material of the piezoelectric layer 12 may alternatively be ZnO, PZT, GaN, InN, CdS, CdSe, ZnS, CdTe, ZnTe, GaAs, GaSb, InAs, InSb, GaSe, GaP, AIP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF or the like. The material of the piezoelectric layer 12 may be a single piezoelectric material, or a stack of the above piezoelectric materials. A thickness of the piezoelectric layer 12 is in a range from 10 nm to 100 μm.

In some examples, a material of the second electrode 13 is preferably metal molybdenum, which has a lattice size and a lattice structure very close to those of the material including AlN or doped AlN of the piezoelectric layer 12. The material of the second electrode 13 may alternatively be Al, Cu, Co, Ag, Ti, Pt, Ru, W, Au, or a stack or an alloy of these metals. A thickness of the second electrode 13 is in a range from 1 nm to 10 μm.

Next, a method for manufacturing the bulk acoustic wave resonator in the fifth example will be explained. As shown in FIG. 14, the method specifically includes the following steps S51 to S58.

The step S51 includes providing a base substrate 10.

As an example, the base substrate 10 is made of a single crystal silicon substrate, the step S51 may specifically include; firstly, performing ultrasonic cleaning on the single crystal silicon substrate with deionized water; then putting the cleaned substrate into a mixed solution of H₂SO₄:H₂O=3:1, heated to 250° C. and washed for 15 minutes; putting the substrate into the deionized water for the ultrasonic cleaning; then putting the substrate into a mixed solution of NH₄OH:H₂O=1:6, heated to 80° C. and washed for 15 minutes; taking out the substrate and putting the substrate into deionized water for washing; then, putting the substrate into a mixed solution of HCl:H₂O₂:H₂O=1:1:5, heated to 85° C. and washed for 15 minutes; taking out the substrate and putting the substrate into dilute hydrofluoric acid of HF:H₂O=1:20 for rinsing for 10 seconds to remove an oxide layer on a surface of the substrate; and finally, putting the substrate into the deionized water for the ultrasonic cleaning for 20 minutes, and drying the substrate by using an air knife to finish the whole cleaning process of the base substrate 10.

The step S52 includes forming at least one mirror structure 15 on the base substrate 10.

The step S52 may specifically include; the following steps (a) and (b). In the step (a), a film material for a high acoustic impedance layer 151 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

The step S53 includes forming a first bias resistance layer 17 on a side of at least one mirror structure 15 away from the base substrate 10.

Specifically, in the step S53, a conductive material film having a high resistivity may be deposited, preferably by radio frequency magnetron sputtering (alternatively, direct current magnetron sputtering), alternatively by pulsed laser sputtering (PLD), molecular beam epitaxy (MBE), thermal evaporation, electron beam evaporation or by attaching a metal foil or an alloy foil. Then, a photolithography process including coating photoresist (or spraying photoresist), pre-baking, exposing, developing and post-baking is performed on the conductive material film. Next, an etching process is performed, preferably a wet etching process, or alternatively a dry etching process, thereby forming the first bias resistance layer 17.

The step S54 includes forming a first electrical isolation layer 18 on a side of the first bias resistance layer 17 away from the base substrate 10.

Specifically, the step S54 may include depositing an electrical insulating material, by radio frequency magnetron sputtering, pulsed laser sputtering (PLD), atomic layer deposition (ALD), or plasma chemical vapor deposition (PECVD). Then, a photolithography process including coating photoresist (or spraying photoresist), pre-baking, exposing, developing and post-baking is performed on the electrical insulating material. Next, an etching process is performed, preferably a wet etching process, or alternatively a dry etching process, thereby forming the first electrical isolation layer 18.

The step S55 includes forming a first electrode 11 on a side of the first electrical isolation layer 18 away from the base substrate 10.

When the first electrode 11 is made of a metal material, the step S55 may include depositing a first metal film on the base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation or by attaching a copper foil. Then, a photolithography process including coating photoresist (or spraying photoresist), pre-baking, exposing, developing and post-baking is performed on the first metal film. Next, an etching process is performed, preferably a wet etching process, or alternatively a dry etching process, to form a pattern including the first electrode 11. Finally, a photoresist removing process is performed to form the first electrode.

The step S56 includes forming a piezoelectric layer 12 on a side of the first electrode 11 away from the base substrate 10.

As an example, the piezoelectric layer 12 is of an AlN single-layer structure, in the step S56, a piezoelectric material layer may be formed on a side of the first electrode 11 away from the base substrate 10, and an orientation growth of the piezoelectric material layer may be performed, preferably by radio frequency magnetron sputtering (or direct current magnetron sputtering), and a target material is Al for the piezoelectric material AlN. An AlN C-axis aligned piezoelectric material layer is formed by controlling an air pressure and a temperature of Ar and N₂ and a time and temperature of post-annealing in the deposition, and preferably the growth orientation is (001). The deposition method for the piezoelectric material layer may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is then subjected to a photolithography process including coating glue (or spraying glue), pre-baking, exposing, developing and post-baking. Next, the piezoelectric material layer is etched to form a pattern of the piezoelectric layer 12; a preferred etching process may be a wet etching process or a dry etching process. Finally, a photoresist removing process is performed to form the piezoelectric layer 12.

The step S57 includes forming a second electrode 13 on a side of the piezoelectric layer 12 away from the first electrode 11.

When the second electrode 13 is made of a metal material, the step S57 may specifically include depositing a second metal film on a side of the piezoelectric layer 12 away from the first electrode 11, preferably by direct current magnetron sputtering (alternatively, radio frequency magnetron sputtering), alternatively by pulsed laser sputtering (PLD), molecular beam epitaxy (MBE), thermal evaporation, electron beam evaporation. Then, a photolithography process including coating photoresist (or spraying photoresist), pre-baking, exposing, developing and post-baking is performed on the second metal film. Next, an etching process is performed, preferably a wet etching process, or alternatively a dry etching process, to form a pattern including the second electrode 13. Finally, a photoresist removing process is performed to form the second electrode 13.

The step S58 includes forming an encapsulation layer 16 on a side of the second electrode 13 away from the base substrate 10.

As an example, the encapsulation layer 16 is made of an organic compound material. The step S58 may specifically include performing liquid coating of the organic material, such as spin coating, spraying, ink-jet printing, or transferring or the like, and then performing a heat curing process to form a pattern of the encapsulation layer 16.

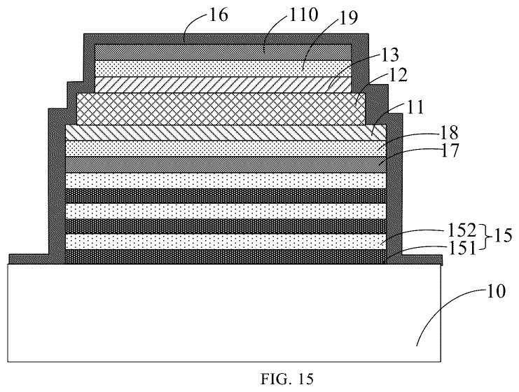

In a sixth example: FIG. 15 is a schematic diagram of a structure of a bulk acoustic wave resonator of a sixth example of an embodiment of the present disclosure. As shown in FIG. 15, the bulk acoustic wave resonator includes a base substrate 10, and at least one acoustic mirror structure 15, a first bias resistance layer 17, a first electrical isolation layer 18, a first electrode 11, a piezoelectric layer 12, a second electrode 13, a second electrical isolation layer 19, and a second bias resistance layer 110 sequentially provided on the base substrate 10. Orthographic projections of any two of the first electrode 11. the piezoelectric layer 12 and the second electrode 13 on the base substrate 10 at least partially overlap with each other. Each acoustic mirror structure 15 includes a first sub-structure and a second sub-structure sequentially arranged along a direction away from the base substrate 10, and an acoustic impedance of a material of the first sub-structure is greater than that of a material of the second sub-structure. For ease of description and understanding, the first sub-structure will be referred to hereinafter as a high acoustic impedance layer 151 and the second sub-structure as a low acoustic impedance layer 152. In this case, a radio frequency signal enters into the bulk acoustic wave resonator, then is converted into an acoustic wave signal through an inverse piezoelectric effect at an interface between the second electrode 13 and the piezoelectric layer 12, and the acoustic wave signal is longitudinally transmitted in the piezoelectric layer 12, and is converted into a radio frequency signal through the piezoelectric effect at an interface between the first electrode 11 and the piezoelectric layer 12, and finally is transmitted outward from the resonator. The first cavity 101 below the bulk acoustic wave resonator and the air layer above the resonator together act as an acoustic reflector, and are configured to confine the acoustic signal within the resonator structure rather than dissipating the acoustic signal out, thereby reducing the losses of the bulk acoustic wave resonator.

When a real-time frequency compensation is performed, a direct current bias voltage is applied between the first bias resistance layer 17 and the second bias resistance layer 110, so that a direct current electric field is generated in the piezoelectric layer 12. When a direction of the direct current electric field is from the first bias resistance layer 17 to the second bias resistance layer 110, an intensity of the electric field is increased from 0 to +100 V/μm along with the increase of the direct current bias voltage, and the resonant frequency of the bulk acoustic wave resonator shifts towards a low frequency. When the direction of the direct current electric field is from the second bias resistance layer 110 to the first bias resistance layer 17, an intensity of the electric field is increased from 0 to −100 V/μm along with the increase of the direct current bias voltage, and the resonant frequency of the bulk acoustic wave resonator shifts towards a high frequency. Under the modulation of direct current electric field, the resonant frequency of the bulk acoustic wave resonator is controlled to move linearly in a range from 28 ppm·f₀/(V/μm) to 58 ppm·f₀/(V/μm); wherein a moving range of the piezoelectric material doped with AlN is greater than that of the piezoelectric material without AlN, f₀ is an initial resonant frequency without the direct current bias voltage, and V/μm is the intensity of the electric field applied to the piezoelectric layer 12. The specific use scene is that when the ambient temperature changes, a temperature drift occurs in the resonant frequency of the bulk acoustic wave resonator (the resonant frequency shifts towards a low frequency along with the increase of the temperature, and towards a high frequency along with the decrease of the temperature), so that a temperature drift occurs in a filter curve of a filter. In this case, by adjusting the direct current bias voltage applied to the piezoelectricity layer 12, the resonant frequency of the bulk acoustic wave resonator shifts towards a direction opposite to a direction of the temperature drift, so that the final effect of the unchanged resonant frequency is realized and the filter curve of the filter is ensured to be unchanged when the ambient temperature changes.

For the sixth example, compared with the fifth example, the second electrical isolation layer 19 and the second bias resistance layer 110 are further provided on the second electrode 13, so as to completely isolate a direct current signal from a radio frequency signal on two opposite sides of the bulk acoustic wave resonator. In this way, it is not necessary to provide a DC isolator outside a piezoelectric filter.

In some examples, an encapsulation layer 16 is further disposed on a side of the second electrode 13 away from the base substrate 10 to isolate moisture and oxygen and avoid device damage.

Further, a material of the encapsulation layer 16 is preferably an organic compound capable of blocking moisture and oxygen, such as polyimide, epoxy, or the like. Alternatively, the material of the encapsulation layer 16 may be an inorganic material such as SiNₓ, Al₂O₃, or the like. The encapsulation layer 16 may be a single layer of material or may be a stack of materials.

In some examples, a material of the base substrate 10 is preferably glass, and may alternatively be Si, sapphire, SiC, GaAs, GaN, InP, BN, ZnO, GaO or the like, and a thickness of the base substrate 10 is in a range from 0.1 μm to 10 mm.

In some examples, the at least one acoustic mirror structure 15 is composed of high acoustic impedance layers 151 and low acoustic impedance layers 152 alternately arranged. An acoustic impedance of a material is equal to a propagation velocity of an acoustic wave in the material multiplied by a density of the material. Theoretically, when a thickness of each high acoustic impedance layer 151 is equal to a quarter of a wavelength of an acoustic wave at a resonant frequency of the bulk acoustic wave resonator propagating in the high acoustic impedance layer 151, and a thickness of each low acoustic impedance layer 152 is equal to a quarter of the wavelength of the acoustic wave at the resonant frequency of the bulk acoustic wave resonator propagating in the low acoustic impedance layer 152, the effect of the high acoustic impedance layers 151 and the low acoustic impedance layers 152 alternately arranged (high/low/high/low . . . , or low/high/low/high . . . ) is equivalent to an acoustic mirror, to reflect the acoustic wave signal leaking from the top. One high acoustic impedance layer 151 and one low acoustic impedance layer 152 as one group form one mirror structure 15, generally 3 groups or 4 groups of the high acoustic impedance layers 151 and the low acoustic impedance layers 152 are needed to achieve a better acoustic reflection effect. Certainly, the greater number of groups may achieve the better acoustic reflection effect, with the increased cost. The number of groups is not limited herein, and the number of the mirror structures 15 may be in a range of 1 to 100. There is no limitation on whether the thickness of each layer is equal to one quarter of the wavelength, and any thickness is acceptable. The high acoustic impedance layer 151 may be made of W, Ir, Pt, Ru, Au, Mo, Ta, Ti, Cu, Ni, Zn, Al, Al₂O₃, Ag, etc., and the common low acoustic impedance layer may be made of SiO₂, Si₃N₄, Mg, rubber, nylon, polyimide, polyethylene, polystyrene, Teflon, etc. The thickness of each high acoustic impedance layer 151 and each low acoustic impedance layer 152 is in a range from 1 nm to 10 μm depending on the different resonance frequencies and the acoustic velocities of different materials.

In some examples, a material of each of the first bias resistance layer 17 and the second bias resistance layer 110 is a conductive material having a high resistivity, preferably ITO, or alternatively IZO, ZnO, IGO, IGZO, W, Mn, Cr, Ti, Ni, constantan alloy, manganin alloy, nichrome alloy, iron-chromium-aluminum alloy, or the like. The first bias resistance layer 17 may be a single material or a stack of the above materials. A thickness of the first bias resistance layer 17 is in a range from 1 nm to 10 μm.

In some embodiments, each of the first electrical isolation layer 18 and the second electrical isolation layer 19 is made of an insulating material, preferably Si₃N₄, or alternatively SiO₂, Al₂O₃, AlN, BN, or the like. The first electrical isolation layer 18 may be a single material or a stack of the above materials. A thickness of the first electrical isolation layer 18 is in a range from 1 nm to 10 μm.

In some examples, a material of the first electrode 11 is preferably metal molybdenum, which has a lattice size and a lattice structure very close to those of the material including AlN or doped AlN of the piezoelectric layer 12. The material of the first electrode 11 may alternatively be Al, Cu, Co, Ag, Ti, Pt, Ru, W, Au, or a stack or an alloy of these metals. A thickness of the first electrode 11 is in a range from 1 nm to 10 μm.

In some examples, the material of the piezoelectric layer 12 is preferably AlN and doped AlN, wherein the doped AlN is, for example, Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N. The material of the piezoelectric layer 12 may alternatively be ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF or the like. The material of the piezoelectric layer 12 may be a single piezoelectric material, or a stack of the above piezoelectric materials. A thickness of the piezoelectric layer 12 is in a range from 10 nm to 100 μm.

In some examples, a material of the second electrode 13 is preferably metal molybdenum, which has a lattice size and a lattice structure very close to those of the material including AlN or doped AlN of the piezoelectric layer 12. The material of the second electrode 13 may alternatively be Al, Cu, Co, Ag, Ti, Pt, Ru, W, Au, or a stack or an alloy of these metals. A thickness of the second electrode 13 is in a range from 1 nm to 10 μm.

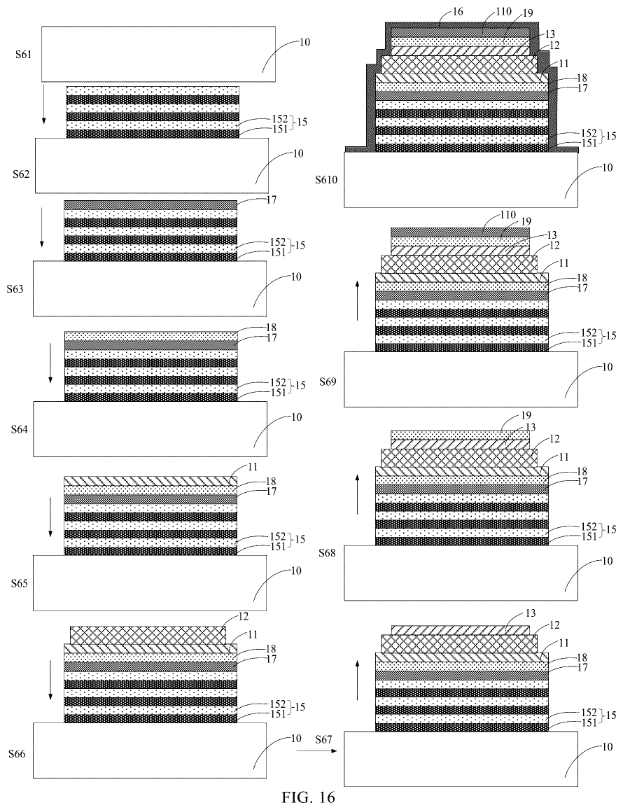

Next, a method of manufacturing the bulk acoustic wave resonator in the sixth example will be explained. As shown in FIG. 16, the method specifically includes the following steps S61 to S610.

The step S61 includes providing a base substrate 10.

As an example, the base substrate 10 is made of a single crystal silicon substrate, the step S61 may specifically include; firstly, performing ultrasonic cleaning on the single crystal silicon substrate with deionized water; then putting the cleaned substrate into a mixed solution of H₂SO₄:H₂O=3:1, heated to 250° C. and washed for 15 minutes; putting the substrate into the deionized water for the ultrasonic cleaning; then putting the substrate into a mixed solution of NH₄OH:H₂O=1:6, heated to 80° C. and washed for 15 minutes; taking out the substrate and putting the substrate into deionized water for washing; then, putting the substrate into a mixed solution of HCl:H₂O₂:H₂O=1:1:5, heated to 85° C. and washed for 15 minutes; taking out the substrate and putting the substrate into dilute hydrofluoric acid of HF:H₂O=1:20 for rinsing for 10 seconds to remove an oxide layer on a surface of the substrate; and finally, putting the substrate into the deionized water for the ultrasonic cleaning for 20 minutes, and drying the substrate by using an air knife to finish the whole cleaning process of the base substrate 10.

The step S62 includes forming at least one mirror structure 15 on the base substrate 10.

The step S62 may specifically include; the following steps (a) and (b). In the step (a), a film material for a high acoustic impedance layer 151 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the high acoustic impedance layer 151 to form the high acoustic impedance layer 151. The etching process is preferably a wet etching process, or alternatively a dry etching process. In the step (b), a film material for a low acoustic impedance layer 152 is firstly deposited, preferably by direct current magnetron sputtering (alternatively, radio frequency magnetron sputtering), alternatively by pulsed laser sputtering (PLD), molecular beam epitaxy (MBE), thermal evaporation, electron beam evaporation; processes including coating glue (or spraying glue), pre-baking, exposing, developing, post-baking and etching are performed on the film for the low acoustic impedance layer 152 to form the low acoustic impedance layer 152. The etching process is preferably a wet etching process, or alternatively a dry etching process. Thereafter, the steps (a) and (b) are repeated until the at least one acoustic mirror structure 15 satisfying the design requirement on the number of layers is obtained.

The step S63 includes forming a first bias resistance layer 17 on a side of at least one mirror structure 15 away from the base substrate 10.

Specifically, in the step S63, a conductive material film having a high resistivity may be deposited, preferably by radio frequency magnetron sputtering (alternatively, direct current magnetron sputtering), alternatively by pulsed laser sputtering (PLD), molecular beam epitaxy (MBE), thermal evaporation, electron beam evaporation or by attaching a metal foil or an alloy foil. Then, a photolithography process including coating photoresist (or spraying photoresist), pre-baking, exposing, developing and post-baking is performed on the conductive material film. Next, an etching process is performed. preferably a wet etching process, or alternatively a dry etching process, thereby forming the first bias resistance layer 17.

The step S64 includes forming a first electrical isolation layer 18 on a side of the first bias resistance layer 17 away from the base substrate 10.

Specifically, the step S64 may include depositing an electrical insulating material, by radio frequency magnetron sputtering, pulsed laser sputtering (PLD), atomic layer deposition (ALD), or plasma chemical vapor deposition (PECVD). Then, a photolithography process including coating photoresist (or spraying photoresist), pre-baking, exposing, developing and post-baking is performed on the electrical insulating material. Next, an etching process is performed, preferably a wet etching process, or alternatively a dry etching process, thereby forming the first electrical isolation layer 18.

The step S65 includes forming a first electrode 11 on a side of the first electrical isolation layer 18 away from the base substrate 10.

When the first electrode 11 is made of a metal material, the step S65 may include depositing a first metal film on the base substrate 10, preferably by direct current magnetron sputtering (alternatively, radio frequency magnetron sputtering), alternatively by pulsed laser sputtering (PLD), molecular beam epitaxy (MBE), thermal evaporation, electron beam evaporation or by attaching a copper foil. Then, a photolithography process including coating photoresist (or spraying photoresist), pre-baking, exposing, developing and post-baking is performed on the first metal film. Next, an etching process is performed, preferably a wet etching process, or alternatively a dry etching process, to form a pattern including the first electrode 11. Finally, a photoresist removing process is performed to form the first electrode.

The step S66 includes forming a piezoelectric layer 12 on a side of the first electrode 11 away from the base substrate 10.

As an example, the piezoelectric layer 12 is of an AlN single-layer structure, in the step S66, a piezoelectric material layer may be formed on a side of the first electrode 11 away from the base substrate 10, and an orientation growth of the piezoelectric material layer may be performed, preferably by radio frequency magnetron sputtering (or direct current magnetron sputtering), and a target material is Al for the piezoelectric material AlN. An AlN C-axis aligned piezoelectric material layer is formed by controlling an air pressure and a temperature of Ar and N₂ and a time and temperature of post-annealing in the deposition, and preferably the growth orientation is (001). The deposition method for the piezoelectric material layer may be selected from pulsed laser sputtering (PLD), molecular beam epitaxy (MBE), metal organic chemical vapor deposition (MOCVD), plasma enhanced chemical vapor deposition (PECVD), and the like. The piezoelectric layer 12 is then subjected to a photolithography process including coating glue (or spraying glue), pre-baking, exposing, developing and post-baking. Next, the piezoelectric material layer is etched to form a pattern of the piezoelectric layer 12; a preferred etching process may be a wet etching process or a dry etching process. Finally, a photoresist removing process is performed to form the piezoelectric layer 12.

The step S67 includes forming a second electrode 13 on a side of the piezoelectric layer 12 away from the first electrode 11.

When the second electrode 13 is made of a metal material, the step S67 may specifically include depositing a second metal film on a side of the piezoelectric layer 12 away from the first electrode 11, preferably by direct current magnetron sputtering (alternatively, radio frequency magnetron sputtering), alternatively by pulsed laser sputtering (PLD), molecular beam epitaxy (MBE), thermal evaporation, electron beam evaporation. Then, a photolithography process including coating photoresist (or spraying photoresist), pre-baking, exposing, developing and post-baking is performed on the second metal film. Next, an etching process is performed, preferably a wet etching process, or alternatively a dry etching process, to form a pattern including the second electrode 13. Finally, a photoresist removing process is performed to form the second electrode 13.

The step S68 includes forming a second electrical isolation layer 19 on a side of the second electrode 13 away from the base substrate 10.

The second electrical isolation layer 19 is formed by the same process as the first electrical isolation layer 18, and therefore, the description thereof is omitted.

The step S69 includes forming a second bias resistance layer 110 on a side of the second electrical isolation layer 19 away from the base substrate 10.

The second bias resistance layer 110 is formed by the same process as the first bias resistance layer 17, and therefore, the description thereof is omitted.

The step S610 includes forming an encapsulation layer 16 on a side of the second electrode 13 away from the base substrate 10.

As an example, the encapsulation layer 16 is made of an organic compound material. The step S610 may specifically include performing liquid coating of the organic material, such as spin coating, spraying, ink-jet printing, or transferring or the like, and then performing a heat curing process to form a pattern of the encapsulation layer 16.

It should be noted that in the above examples of the bulk acoustic wave resonator, only the cases are given that the first electrical isolation layer 18 and the first bias resistance layer 17 are formed on a side of the first electrode 11 close to the base substrate 10, and the second electrical isolation layer 19 and the second bias resistance layer 110 are formed on a side of the second electrode 13 away from the base substrate 10. It should be understood that it is also possible to form the second electrical isolation layer 19 and the second bias resistance layer 110 on a side of the second electrode 13 away from the base substrate 10.

The embodiment of the present disclosure further provides an electronic device, which may include the bulk acoustic wave resonator of any one of the above embodiments.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure. and such changes and modifications also fall within the scope of the present disclosure.

1. A bulk acoustic wave resonator, comprising; a base substrate, a first electrode, a piezoelectric layer, and a second electrode; wherein the first electrode is on the base substrate, the second electrode is on a side of the first electrode away from the base substrate, the piezoelectric layer is between the first electrode and the second electrode; and orthographic projections of any two of the first electrode, the piezoelectric layer and the second electrode on the base substrate at least partially overlap with each other; wherein the bulk acoustic wave resonator further comprises:
a first bias resistance layer on a side of the first electrode close to the base substrate, and a first electric isolation layer between the first bias resistance layer and the first electrode; wherein the first bias resistance layer has a high-resistivity material; and/or
a second bias resistance layer on a side of the second electrode away from the base substrate, and a second electric isolation layer between the second bias resistance layer and the second electrode; wherein the second bias resistance layer has a high-resistivity material.

2. The bulk acoustic wave resonator according to claim 1, wherein the base substrate comprises a first cavity penetrating through the base substrate in a thickness direction of the base substrate.

3. The bulk acoustic wave resonator according to claim 1, further comprising at least one mirror structure on a side of the base substrate close to the first electrode; wherein the first bias resistance layer is arranged on the base substrate, the at least one mirror structure is arranged on a side of the first bias resistance layer close to the base substrate; and
each of the at least one mirror structure comprises a first sub-structure and a second sub-structure sequentially arranged along a direction away from the base substrate, and an acoustic impedance of a material of the first sub-structure is greater than that of a material of the second sub-structure.

4. The bulk acoustic wave resonator according to claim 1, wherein the bulk acoustic wave resonator comprises the first bias resistance layer, and the first bias resistance layer is a single layer structure having a material selected from any one of ITO, IZO, ZnO, IGO, IGZO, W, Mn, Cr, Ti, Ni, constantan alloy, manganin alloy, nichrome alloy, or iron-chromium-aluminum alloy, or a laminated structure having materials selected from any multiple ones of ITO, IZO, ZnO, IGO, IGZO, W, Mn, Cr, Ti, Ni, constantan alloy, manganin alloy, nichrome alloy, or iron-chromium-aluminum alloy.

5. The bulk acoustic wave resonator according to claim 1, wherein the bulk acoustic wave resonator comprises the second bias resistance layer, and the second bias resistance layer is a single layer structure having a material selected from any one of ITO, IZO, ZnO, IGO, IGZO, W, Mn, Cr, Ti, Ni, constantan alloy, manganin alloy, nichrome alloy, iron-chromium-aluminum alloy, or a laminated structure having materials selected from any multiple ones of ITO, IZO, ZnO, IGO, IGZO, W, Mn, Cr, Ti, Ni, constantan alloy, manganin alloy, nichrome alloy, iron-chromium-aluminum alloy.

6. The bulk acoustic wave resonator according to claim 1, wherein the bulk acoustic wave resonator comprises the first electrical isolation layer, and the first electrical isolation layer is a single layer structure having a material selected from any one of Si₃N₄, SiO₂, Al₂O₃, AlN, or BN, or a laminated structure having materials selected from any multiple ones of Si₃N₄, SiO₂, Al₂O₃, AlN, or BN.

7. The bulk acoustic wave resonator according to claim 1, wherein the bulk acoustic wave resonator comprises the second electrical isolation layer, and the second electrical isolation layer is a single layer structure having a material selected from any one of Si₃N₄, SiO₂, Al₂O₃, AlN, or BN, or a laminated structure having materials selected from any multiple ones of Si₃N₄, SiO₂, Al₂O₃, AlN, or BN.

8. The bulk acoustic wave resonator according to claim 1, wherein the base substrate has a material selected from any one of glass, Si, sapphire, SiC, GaAs, GaN, InP, BN, ZnO, or GaO.

9. The bulk acoustic wave resonator according to claim 1, wherein the piezoelectric layer has a material selected from any one of AlN, doped AlN, ZnO, PZT, GaN, InN, CdS, CdSe, ZnS, CdTe, ZnTe, GaAs, GaSb, InAs, InSb, GaSe, GaP, AIP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF, wherein the doped AlN comprises any one of Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N.

10. The bulk acoustic wave resonator according to claim 1, wherein each of the first electrode and the second electrode has a material selected from any one of Mo, Al, Cu, Co, Ag, Ti, Pt, Ru, W, or Au.

11. A method for manufacturing a bulk acoustic wave resonator, comprising; sequentially forming a first electrode, a piezoelectric layer and a second electrode on a first base substrate, wherein orthographic projections of any two of the first electrode, the piezoelectric layer and the second electrode on the first base substrate at least partially overlap with each other; wherein
the method further comprises; forming a first bias resistance layer on a side of the first electrode close to the base substrate, and forming a first electric isolation layer between the first bias resistance layer and the first electrode; wherein the first bias resistance layer is made of a high-resistivity material; and/or
forming a second bias resistance layer on a side of the second electrode away from the base substrate, and forming a second electric isolation layer between the second bias resistance layer and the second electrode; wherein the second bias resistance layer is made of a high-resistivity material.

12. The method according to claim 11, further comprising:
treating the base substrate to form a first cavity penetrating through the base substrate in a thickness direction of the base substrate.

13. The method according to claim 11, further comprising:
forming at least one mirror structure on a side of the base substrate close to the first electrode; wherein the first bias resistance layer is formed on the base substrate, the at least one mirror structure is formed on a side of the first bias resistance layer close to the base substrate; and
the forming the at least one mirror structure comprises sequentially forming a first sub-structure and a second sub-structure along a direction away from the base substrate, and an acoustic impedance of a material of the first sub-structure is greater than that of a material of the second sub-structure.

14. The method according to claim 11, wherein the bulk acoustic wave resonator comprises the first bias resistance layer, and the first bias resistance layer is a single layer structure made of any one of ITO, IZO, ZnO, IGO, IGZO, W, Mn, Cr, Ti, Ni, constantan alloy, manganin alloy, nichrome alloy, or iron-chromium-aluminum alloy, or a laminated structure made of any multiple ones of ITO, IZO, ZnO, IGO, IGZO, W, Mn, Cr, Ti, Ni, constantan alloy, manganin alloy, nichrome alloy, or iron-chromium-aluminum alloy.

15. The method according to claim 11, wherein the bulk acoustic wave resonator comprises the second bias resistance layer, and the second bias resistance layer is a single layer structure made of any one of ITO, IZO, ZnO, IGO, IGZO, W, Mn, Cr, Ti, Ni, constantan alloy, manganin alloy, nichrome alloy, iron-chromium-aluminum alloy, or a laminated structure made of any multiple ones of ITO, IZO, ZnO, IGO, IGZO, W, Mn, Cr, Ti, Ni, constantan alloy, manganin alloy, nichrome alloy, iron-chromium-aluminum alloy.

16. The method according to claim 11, wherein the bulk acoustic wave resonator comprises the first electrical isolation layer, and the first electrical isolation layer is a single layer structure made of any one of Si₃N₄, SiO₂, Al₂O₃, AlN, or BN, or a laminated structure made of any multiple ones of Si₃N₄, SiO₂, Al₂O₃, AlN, or BN.

17. The method according to claim 11, wherein the bulk acoustic wave resonator comprises the second electrical isolation layer, and the second electrical isolation layer is a single layer structure made of any one of Si₃N₄, SiO₂, Al₂O₃, AlN, or BN, or a laminated structure made of any multiple ones of Si₃N₄, SiO₂, Al₂O₃, AlN, or BN.

18. The method according to claim 11, wherein the base substrate is made of any one of glass, Si, sapphire, SiC, GaAs, GaN, InP, BN, ZnO, or GaO; and/or
the piezoelectric layer is made of any one of AlN, doped AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, or PVDF, wherein the doped AlN comprises any one of Al₍₁₋ₓ₎ScₓN, Al₍₁₋ₓ₎CrₓN, Al₍₁₋ₓ₎YₓN, Al₍₁₋ₓ₎TiₓN, Al₍₁₋ₓ₎ZrₓN, Al₍₁₋ₓ₎HfₓN, Al₍₁₋ₓ₎YbₓN, Al₍₁₋ₓ₎TaₓN, Mg_{0.5x}Nb_{0.5x}Al₍₁₋ₓ₎N, Mg_{0.5x}Ti_{0.5x}Al₍₁₋ₓ₎N, Mg_{0.5x}Zr_{0.5x}Al₍₁₋ₓ₎N, Mg_{0.5x}Hf_{0.5x}Al₍₁₋ₓ₎N, Mg_{0.5x}Si_{0.5x}Al₍₁₋ₓ₎N, Zn_{0.25}Ti_{0.25}Al_{0.5}N, Zn_{0.25}Zr_{0.25}Al_{0.5}N, or Zn_{0.25}Hf_{0.25}Al_{0.5}N.

19. (canceled)

20. The method according to claim 11, wherein each of the first electrode and the second electrode is made of any one of Mo, Al, Cu, Co, Ag, Ti, Pt, Ru, W, or Au.

21. An electronic device, comprising the bulk acoustic wave resonator according to claim 1.
